(19) United States
(12) Patent Application Publication
(10) Pub. No.: US 2026/0026282 A1
(43) Pub. Date: Jan. 22, 2026

(54) METHOD OF MANUFACTURING SEMICONDUCTOR DEVICE BY USING LOW-TEMPERATURE PLASMA ETCHING PROCESS

(71) Applicant: SAMSUNG ELECTRONICS CO, LTD., Suwon-si (KR)

(72) Inventors: Buseo CHOI, Suwon-si (KR); Shingo NAKAMURA, Osaka (JP); Takehiko KEZUKA, Osaka (JP); Heechul MOON, Suwon-si (KR); Wonwoong CHUNG, Suwon-si (KR); Younjoung CHO, Suwon-si (KR)

(73) Assignees: SAMSUNG ELECTRONICS CO, LTD., Suwon-si (KR); DAIKIN INDUSTRIES, LTD., Osaka (JP)

(21) Appl. No.: 19/089,724

(22) Filed: Mar. 25, 2025

(30) Foreign Application Priority Data
Jul. 17, 2024 (KR) 10-2024-0094607

(51) Int. Cl. H01L 21/311; H10D 1/00

(52) U.S. Cl. CPC H01L 21/31144; H01L 21/31116; H10D 1/041

(57) ABSTRACT

Provided is a method of manufacturing a semiconductor device, the method including forming a first mold structure and a second mold structure on a semiconductor structure, the second mold structure being spaced apart from the first mold structure in a horizontal direction, the first mold structure including first insulating films and second insulating films different from the first insulating films alternately stacked one-by-one, and the second mold structure including a third insulating film including a material same as a material of each of the first insulating films, forming a mask pattern on the first mold structure and the second mold structure, and etching, using a first etching gas, the first mold structure and the second mold structure based on the mask pattern, wherein the first etching gas includes oxygen-containing fluorocarbon.

### CROSS-REFERENCE TO RELATED APPLICATION

This application is based on and claims priority under 35 U.S.C. § 119 to Korean Patent Application No. 10-2024-0094607, filed on Jul. 17, 2024, in the Korean Intellectual Property Office, the disclosure of which is incorporated by reference herein in its entirety.

### BACKGROUND

The present disclosure relates to a method of manufacturing a semiconductor device by using a low-temperature plasma etching process.

As geometric structures on semiconductor substrates have continued to be reduced and the types of structures have evolved, a lot of challenges have occurred in etching processes. In particular, when semiconductor devices including components having high aspect ratios are manufactured, issues may occur from the difference in etch rate between two different insulating materials. For example, when a first mold structure, in which two different insulating materials are alternately stacked one-by-one, and a second mold structure, in which only one insulating material is arranged, are simultaneously etched, the first mold structure and the second mold structure may respectively have different etch depths through etching for the same time period. In this case, the degree of difficulty in a process of simultaneously forming patterns from the first mold structure and the second mold structure may increase.

### SUMMARY

One or more embodiments provide a method of manufacturing a semiconductor device that may have improved electrical characteristics and reliability.

Further, one or more embodiments also provide a method of manufacturing a semiconductor device, which may allow the degree of difficulty and cost in a manufacturing process to be reduced.

Embodiments of the disclosure are not limited to the above aspects, and the above and other aspects of the disclosure will be clearly understood by those of ordinary skill in the art from the following description.

According to an aspect of one or more embodiments, there is provided a method of manufacturing a semiconductor device, the method including forming a first mold structure and a second mold structure on a semiconductor structure, the second mold structure being spaced apart from the first mold structure in a horizontal direction, the first mold structure including first insulating films and second insulating films different from the first insulating films alternately stacked one-by-one, and the second mold structure including a third insulating film including a material same as a material of each of the first insulating films, forming a mask pattern on the first mold structure and the second mold structure, and etching, using a first etching gas, the first mold structure and the second mold structure based on the mask pattern, wherein the first etching gas includes oxygen-containing fluorocarbon.

According to another aspect of one or more embodiments, there is provided a method of manufacturing a semiconductor device, the method including forming an insulating pattern on a substrate, forming a conductive contact in the insulating pattern, forming an etch stop film on the insulating pattern and the conductive contact, forming a mold structure on the etch stop film, the mold structure including a first mold film, a lower support film, a second mold film, and an upper support film that are stacked in that order, the first mold film and the second mold film including a first material, the lower support film and the upper support film including a second material, and the first material and the second material respectively having etch selectivities with respect to each other, forming a mask pattern on the mold structure, and etching, using a first etching gas, the mold structure based on the mask pattern, wherein a via hole is formed through the mold structure and the etch stop film based on the etching, and wherein the first etching gas includes oxygen-containing fluorocarbon.

According to still another aspect of one or more embodiments, there is provided a method of manufacturing a semiconductor device, the method including forming a first substrate including a cell array area and a contact area that is adjacent to the first substrate, forming a peripheral circuit structure on the first substrate, the peripheral circuit structure including peripheral circuit transistors, forming a mold structure on the peripheral circuit structure, the mold structure including interlayer dielectrics and sacrificial films that are alternately stacked one-by-one, each of the interlayer dielectrics including a first material, each of the sacrificial films including a second material, and the first material and the second material respectively having etch selectivities with respect to each other, trimming the mold structure such that the mold structure has a stepped structure in the contact area, forming a planarization insulating film on the stepped structure, and forming vertical channel holes, a first through-structure hole, and a second through-structure hole simultaneously such that the vertical channel holes pass through the mold structure in the cell array area, the first through-structure hole passes through the planarization insulating film and the mold structure in the contact area, and the second through-structure hole passes through the planarization insulating film in the contact area, wherein the forming of the vertical channel holes, the first through-structure hole, and the second through-structure hole includes etching, using a first etching gas, the mold structure and the planarization insulating film, and wherein the first etching gas includes oxygen-containing fluorocarbon.

### BRIEF DESCRIPTION OF THE DRAWINGS

Embodiments will be more clearly understood from the following detailed description taken in conjunction with the accompanying drawings, in which:

FIG. 1 is a flowchart illustrating a method of manufacturing a semiconductor device by using a low-temperature plasma etching process, according to one or more embodiments;

FIGS. 2A, 2B, 2C, and 2D are cross-sectional views respectively illustrating a sequence of processes of a method of manufacturing a semiconductor device by using a low-temperature plasma etching process, according to one or more embodiments;

FIG. 3 is a diagram illustrating an etch rate of each of a silicon oxide (SiO₂) film, a silicon nitride (SiN) film, a silicon (Si) film, and an amorphous carbon layer (ACL) depending on flow rates of carbon tetrafluoride (CF₄) gas, in a related example;

FIG. 4 is a diagram illustrating an etch rate of each of a SiO₂ film, a SiN film, a Si film, and an ACL depending on flow rates of CF₃OCFCF₂ gas, in an experimental example;

FIG. 5 is a plan view illustrating a semiconductor device according to one or more embodiments;

FIG. 6 is a cross-sectional view of the semiconductor device of FIG. 5, taken along a line A-A′ of FIG. 5;

FIGS. 7, 8, 9, 10, 11, 12, 13, and 14 are diagrams illustrating a method of manufacturing the semiconductor device of FIG. 6, and in particular, FIGS. 7 and 12 are plan views illustrating the method of manufacturing the semiconductor device of FIG. 6, and FIGS. 8 to 11, 13, and 14 are cross-sectional views illustrating the method of manufacturing the semiconductor device of FIG. 6;

FIG. 15 is a plan view illustrating a semiconductor device according to one or more embodiments;

FIG. 16A is a cross-sectional view of the semiconductor device of FIG. 15, taken along a line B-B′ of FIG. 15;

FIG. 16B is a cross-sectional view of the semiconductor device of FIG. 15, taken along a line C-C′ of FIG. 15; and

FIGS. 17A, 17B, 18A, 18B, 19A, and 19B are diagrams illustrating a method of manufacturing a semiconductor device, according to one or more embodiments, and in particular, FIGS. 17A, 18A, and 19A are cross-sectional views taken along the line B-B′ of FIG. 15, and FIGS. 17B, 18B, and 19B are cross-sectional views taken along the line C-C′ of FIG. 15.

### DETAILED DESCRIPTION

Hereinafter, embodiments will be described in detail with reference to the accompanying drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

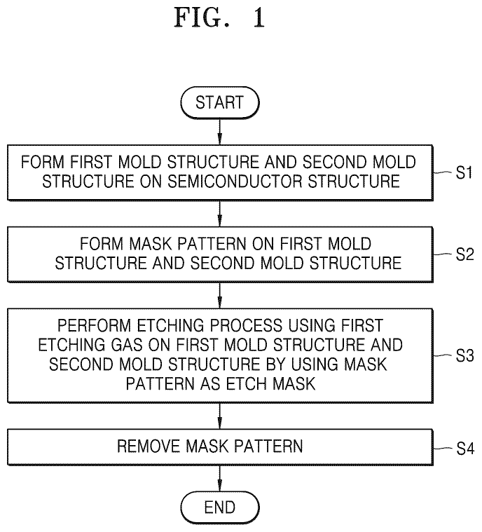

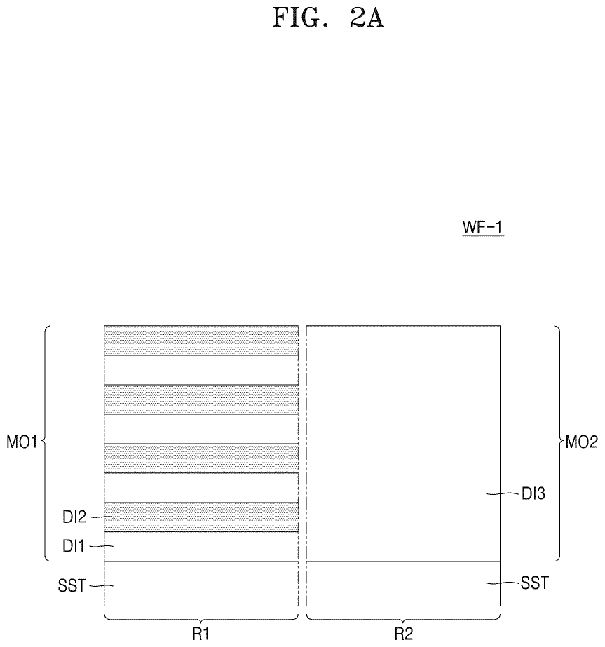

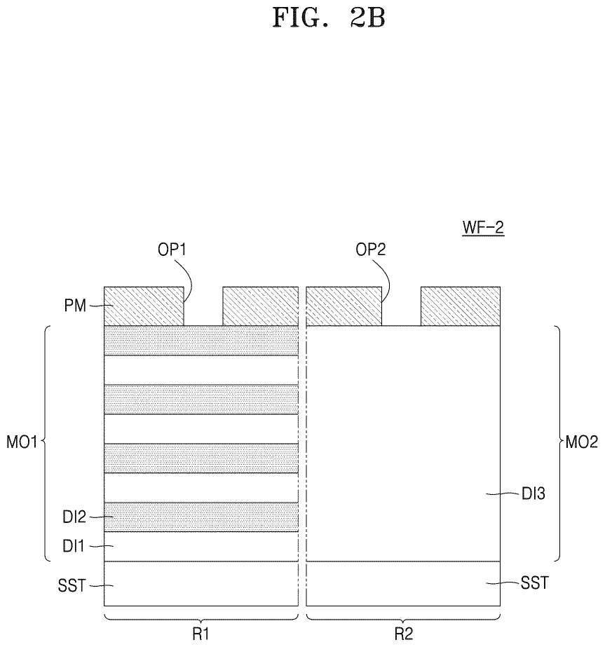

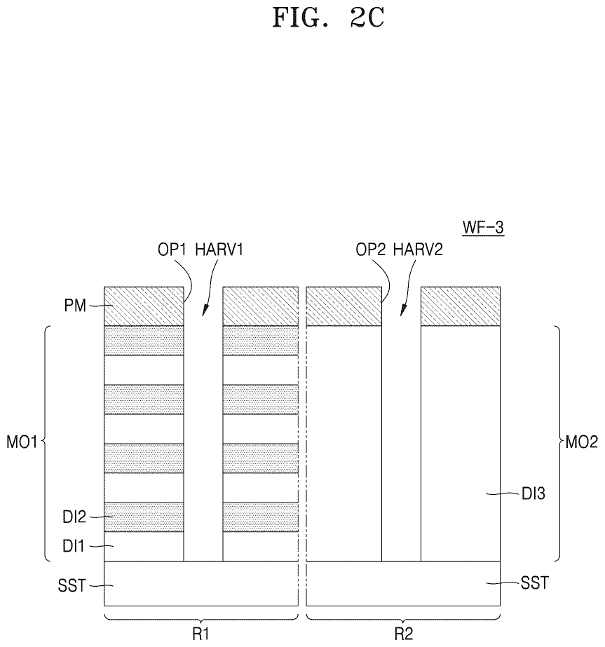

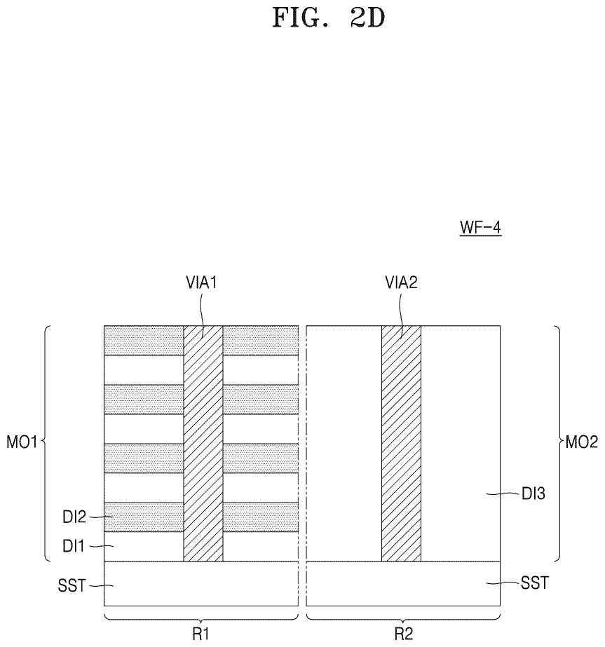

FIG. 1 is a flowchart illustrating a method of manufacturing a semiconductor device by using a low-temperature plasma etching process, according to one or more embodiments. FIGS. 2A to 2D are cross-sectional views respectively illustrating a sequence of processes of a method of manufacturing a semiconductor device by using a low-temperature plasma etching process, according to one or more embodiments.

Referring to FIGS. 1 and 2A, the method of manufacturing a semiconductor device by using a low-temperature plasma etching process may include forming a first mold structure MO1 and a second mold structure MO2 on a semiconductor structure SST (S1). A semiconductor device WF-1 in a first state may be formed by forming the first mold structure MO1 and the second mold structure MO2 on the semiconductor structure SST (S1).

The semiconductor structure SST may include a substrate including a semiconductor material. The semiconductor material may include silicon (Si) or germanium (Ge). However, embodiments are not limited thereto. For example, the semiconductor structure SST may include a compound semiconductor, such as silicon-germanium (SiGe), silicon carbide (SiC), gallium arsenide (GaAs), indium gallium arsenide (InGaAs), or indium phosphide (InP). The semiconductor structure SST may include a silicon-on-insulator (SOI) structure. For example, the semiconductor structure SST may include a buried oxide (BOX) layer.

The semiconductor structure SST may include a device having a specific circuit structure. For example, the semiconductor structure SST may include a device structure, such as dynamic random access memory (DRAM), NAND flash, ferroelectric random access memory (FRAM), resistive random access memory (RRAM), phase-change random access memory (PRAM), magnetoresistive random access memory (MRAM), an application processor (AP), or an application-specific integrated circuit (ASIC).

The semiconductor structure SST may include a first area R1 and a second area R2 that is adjacent to the first area R1 in a horizontal direction. The first area R1 and the second area R2 may be spaced apart from each other in the horizontal direction. In the first area R1, the first mold structure MO1 may be arranged on the semiconductor structure SST. In the second area R2, the second mold structure MO2 may be arranged on the semiconductor structure SST.

The first mold structure MO1 may include a first insulating film DI1 and a second insulating film DI2 that are different from each other. The first insulating film DI1 and the second insulating film DI2 may be alternately stacked one-by-one on the semiconductor structure SST. The first insulating film DI1 and the second insulating film DI2 may each include an insulating material. For example, the first insulating film DI1 and the second insulating film DI2 may include materials having etch selectivities with respect to each other, respectively. For example, the first insulating film DI1 may include silicon oxide and the second insulating film DI2 may include silicon nitride.

The second mold structure MO2 may include a third insulating film DI3. The third insulating film DI3 may be stacked on the semiconductor structure SST. The third insulating film DI3 may include an insulating material. For example, the third insulating film DI3 may include the same material as the first insulating film DI1. For example, the third insulating film DI3 may include silicon oxide.

Referring to FIGS. 1 and 2B, forming a first mask pattern PM on the first mold structure MO1 and the second mold structure MO2 (S2) may be performed on a semiconductor device WF-1 (see FIG. 2A) in the first state, thereby forming a semiconductor device WF-2 in a second state.

The forming of the first mask pattern PM may include forming a mask film on the first mold structure MO1 and the second mold structure MO2 and performing light-exposure and development processes on the mask film. The first mask pattern PM may include a first opening OP1 and a second opening OP2. The first opening OP1 may expose a portion of an upper surface of the first mold structure MO1. The second opening OP2 may expose a portion of an upper surface of the second mold structure MO2.

The first mask pattern PM may include a silicon-based material or a carbon-based material. For example, the first mask pattern PM may include an amorphous carbon layer (ACL). For example, the first mask pattern PM may include monocrystalline or polycrystalline silicon. The first mask pattern PM may include monocrystalline or polycrystalline silicon doped with no other elements. However, embodiments are not limited thereto. For example, the first mask pattern PM may include monocrystalline or polycrystalline silicon doped with carbon (C), boron (B), phosphorus (P), or a metal, or the first mask pattern PM may include a photoresist material.

Referring to FIGS. 1 and 2C, an etching process of the first mold structure MO1 and the second mold structure MO2 by using a first etching gas and using the first mask pattern PM as an etch mask may be performed on the semiconductor device WF-2 (see FIG. 2B) in the second state (S3), thereby forming a semiconductor device WF-3 in a third state.

Through the etching process using the first etching gas, a first via hole HARV1 may be formed in the first mold structure MO1 and a second via hole HARV2 may be formed in the second mold structure MO2. The first via hole HARV1 may vertically overlap the first opening OP1. The first via hole HARV1 may pass through the first mold structure MO1. A portion of the upper surface of the semiconductor structure SST may be exposed by the first via hole HARV1. The second via hole HARV2 may vertically overlap the second opening OP2. The second via hole HARV2 may pass through the second mold structure MO2. A portion of the upper surface of the semiconductor structure SST may be exposed by the second via hole HARV2. The first via hole HARV1 and the second via hole HARV2 may be formed at the same time (simultaneously).

The first via hole HARV1 and the second via hole HARV2 may each have a relatively high aspect ratio. For example, the vertical height of the first via hole HARV1 may be 15 or more times greater than the horizontal width of the first via hole HARV1, but embodiments are not limited thereto. For example, the vertical height of the second via hole HARV2 may be 15 or more times greater than the horizontal width of the second via hole HARV2, but embodiments are not limited thereto.

The first etching gas may include oxygen-containing fluorocarbon. For example, the first etching gas may include a material having a formula of CxFyOz (wherein 1≤x≤5, 2x−2≤y≤2x+2, 1≤z<x, and x, y, and z are each a natural number). For example, the first etching gas may include a material having an ether structure such as trifluoromethyl R(1)-O—CR(2)═CR(3)R(4) (wherein R(1), R(2), R(3), and R(4)=CaFb, 0≤a≤3, b=2a+1, and a and b are each a natural number), for example, at least one of trifluorovinyl ether (CF₃OCFCF₂), pentafluoroethyl trifluorovinyl ether (C₄F₈O), and decafluoropropylvinyl ether (C₅F₁₀O).

The etching process using the first etching gas may include a low-temperature etching process. The etching process using the first etching gas may be performed at about-100° C. to about 0° C. The etching process using the first etching gas may use inductively coupled plasma (ICP), capacitively coupled plasma (CCP), helicon wave plasma, electron cyclotron resonance (ECR) plasma, or the like.

The etching process may further include a second etching gas in addition to the first etching gas. The second etching gas may include molecules of a single type or molecules of two or more types. For example, the second etching gas may include at least one of hydrogen (H₂), hydrogen fluoride (HF), nitrogen fluoride, phosphorus fluoride, sulfur fluoride, fluorocarbon, hydrofluorocarbon, and/or a halogen element-containing gas.

For example, nitrogen fluoride may include nitrogen trifluoride (NF₃). For example, phosphorus fluoride may include phosphorus trifluoride (PF₃), phosphorus pentafluoride (PF₅), or the like. For example, sulfur fluoride may include sulfur hexafluoride (SF₆), sulfur tetrafluoride (SF₄), or the like. Fluorocarbon may include tetrafluoromethane (CF₄), hexafluoroethane (C₂F₆), octafluoropropane (C₃F₈), or the like. For example, hydrofluorocarbon may include monofluoromethane (CH₃F), difluoromethane (CH₂F₂), or the like. For example, the halogen element-containing gas may include hydrogen bromide (HBr) and/or chlorine (Cl₂).

When fluorocarbon or hydrofluorocarbon is used to form the first via hole HARV1 and the second via hole HARV2 each having a relatively high aspect ratio, an etch rate of the first insulating film DI1 may be different from an etch rate of the second insulating film DI2. For example, when each of the first insulating film DI1 and the third insulating film DI3 includes silicon oxide and the second insulating film DI2 includes silicon nitride, the etch rate of each of the first insulating film DI1 and the third insulating film DI3 may be less than the etch rate of the second insulating film DI2. Therefore, when it is attempted to simultaneously form the first via hole HARV1 and the second via hole HARV2 by an etching process, the second via hole HARV2 may not be formed yet in the second mold structure MO2 at a time point at which the first via hole HARV1 is formed in the first mold structure MO1. This may be because the first mold structure MO1 has a structure in which the first insulating film DI1 and the second insulating film DI2 respectively having different etch rates by fluorocarbon and hydrofluorocarbon are alternately stacked one-by-one and because the second mold structure MO2 includes only the single third insulating film DI3. The third insulating film DI3 may include the same material as the first insulating film DI1. Due to the reasons set forth above, because it is difficult to simultaneously form the first via hole HARV1 and the second via hole HARV2, the degree of difficulty and cost in a manufacturing process may increase. In addition, because the second via hole HARV2 may not be completely formed at a time point at which the first via hole HARV1 is formed, an electrical connection between components formed in a subsequent process may be unstable. Therefore, the electrical characteristics and reliability of a semiconductor device may deteriorate.

The method of manufacturing a semiconductor device by using a low-temperature plasma etching process, according to one or more embodiments, may include a first etching gas in an etching process. The first etching gas may include oxygen-containing fluorocarbon. For example, the first etching gas may include a material having a formula of CxFyOz (wherein 1≤x≤5, 2x−2≤y≤2x+2, 1≤z<x, and x, y, and z are each a natural number). For example, the first etching gas may include a material having an ether structure, such as trifluoromethyl R(1)-O—CR(2)═CR(3)R(4) (wherein R(1), R(2), R(3), and R(4)=CaFb, 0≤a≤3, b=2a+1, and a and b are each a natural number), for example, at least one of trifluorovinyl ether (CF₃OCFCF₂), pentafluoroethyl trifluorovinyl ether (C₄F₈O), and decafluoropropylvinyl ether (C₅F₁₀O).

During the etching process, a flow rate of the first etching gas supplied to the first mold structure MO1 and the second mold structure MO2 may be flexibly adjusted. For example, when the sum of flow rates of gases except for the first etching gas is assumed to be 100, the flow rate of the first etching gas may have a flow rate ratio of about 100:20 to about 100:40. As described below, in the case where the sum of the flow rates of the gases except for the first etching gas is assumed to be 100, embodiments may have the greatest effects when the flow rate of the first etching gas has a flow rate ratio of about 100:20 to about 100:40.

When the first etching gas is used to form the first via hole HARV1 and the second via hole HARV2 each having a relatively high aspect ratio, the difference between the etch rate of the first insulating film DI1 and the etch rate of the second insulating film DI2 may decrease. When the first etching gas is used to form the first via hole HARV1 and the second via hole HARV2 each having a relatively high aspect ratio, the difference between the etch rate of the third insulating film DI3 and the etch rate of the second insulating film DI2 may be reduced. For example, when each of the first insulating film DI1 and the third insulating film DI3 includes silicon oxide and the second insulating film DI2 includes silicon nitride, the difference between the etch rate of each of the first insulating film DI1 and the third insulating film DI3 and the etch rate of the second insulating film DI2 may be reduced. Therefore, when it is attempted to simultaneously form the first via hole HARV1 and the second via hole HARV2 by an etching process, the second via hole HARV2 may be formed in the second mold structure MO2 simultaneously at the time point at which the first via hole HARV1 is formed in the first mold structure MO1. Due to the reasons set forth above, the degree of difficulty and cost in a manufacturing process of a semiconductor device may be reduced. In addition, because the second via hole HARV2 may be completely formed at the time point at which the first via hole HARV1 is formed, an electrical connection between components formed in a subsequent process may be more stable. Therefore, the electrical characteristics and reliability of the semiconductor device may improve.

When there is a relatively large difference between the etch rate of the first insulating film DI1 and the etch rate of the second insulating film DI2, it may be difficult to form the first via hole HARV1 by performing an etching process on the first mold structure MO1. This is because an etch depth is more likely to be more than or less than a target etch depth even with a minor change in process conditions. On the other hand, according to the one or more embodiments, the difference between the etch rate of each of the first insulating film DI1 and the third insulating film DI3 and the etch rate of the second insulating film DI2 may be reduced. Therefore, in a structure in which different insulating films are alternately stacked one-by-one as in the first mold structure MO1, the difficulty in a method of forming the first via hole HARV1 may decrease.

In addition, when the first mask pattern PM includes a silicon-based material or a carbon-based material and oxygen-containing fluorocarbon is used as the first etching gas, an etch rate of the first mask pattern PM may be reduced. Therefore, the etch selectivity of the first mask pattern PM with respect to the first to third insulating films DI1, DI2, and DI3 may improve.

In the method of manufacturing a semiconductor device by using a low-temperature plasma etching process, according to one or more embodiments, an etching process may be performed at a temperature of about −100° C. to about 0° C. Therefore, an adsorption rate of etching gases (for example, the first etching gas) that are present in a gas phase may be increased by decreasing a surface temperature of a component that is undergoing the etching process, thereby increasing the etch rate of the component. In addition, unnecessary surface chemical reactions may be reduced due to the low temperature. Due to the reasons set forth above, the selectivity between an etch target and an etch mask may improve and etching in the horizontal direction may be reduced or prevented.

When hydrogen is used as the second etching gas, the etch rate may significantly improve. When fluorocarbon, hydrofluorocarbon, or a halogen element-containing gas is used as the second etching gas, an inner side surface of the component that is being etched may be protected while the etching process is being performed.

Referring to FIGS. 1 and 2D, the first mask pattern PM may be removed from the semiconductor device WF-3 (see FIG. 2C) in the third state (S4). Next, a first via VIA1, which fills the first via hole HARV1 (see FIG. 2C), and a second via hole VIA2, which fills the second via hole HARV2 (see FIG. 2C), may be formed. The first via VIA1 and the second via VIA2 may each have a relatively high aspect ratio. The first via VIA1 and the second via VIA2 may each include, but are not limited to, a conductive material.

In Related Example and Experimental Example, conditions of flow rates depending on the types of etching gases are shown in Table 1.

TABLE 1
Flow rates depending on types of etching gases (sccm)

| | CF₃OCFCF₂ | CF₄ | H₂ | CH₂F₂ | Cl₂ |
|---|---|---|---|---|---|
| Related | — | 30 | 50 | 40 | 10 |
| Example | | | | | |
| Experimental | 30 | | 50 | 40 | 10 |
| Example | | | | | |

Both of Related Example and Experimental Example were performed at a temperature of −30° C. In both of Related Example and Experimental Example, one of a SiO₂ film, a SiN film, a Si film, and an ACL was deposited on a wafer substrate, followed by performing a low-temperature plasma etching process on the wafer substrate. Gases used for the etching process were supplied to the wafer substrate. A silicon substrate was used as the wafer substrate. Inductively coupled plasma was used as a plasma source. Except that CF₄ was used as an etching gas in Related Example and CF₃OCFCF₂ was used as an etching gas in Experimental Example, all other conditions were equally applied. H₂, CH₂F₂, and Cl₂ were commonly supplied to the wafer substrate in both Related Example and Experimental Example, and the flow rates of the respective gases were equally applied to both Related Example and Experimental Example. The flow rate was measured in units of sccm.

In Related Example and Experimental Example, results regarding the etch rate of SiO₂, SiN, Si, or the ACL are shown in Table 2.

TABLE 2
Etch rates depending on types of insulating films (Å/min)

| Type of insulating film | SiO₂ | SiN | Si | ACL |
|---|---|---|---|---|
| Related Example | 3479 | 4962 | 964 | 461 |
| Experimental | 3319 | 3574 | 589 | 472 |
| Example | | | | |

In Related Example and Experimental Example, results regarding the ratio of the etch rate of the SiO₂ film to the etch rate of the SiN film and the ratio of the etch rate of the SiO₂ film to the etch rate of the Si film are shown in Table 3. The ratio between the etch rates may be alternatively referred to as the term “etch selectivity”.

TABLE 3
Ratio between etch rates (etch selectivity)

| | Ratio of etch rate of | Ratio of etch rate of |
|---|---|---|
| | SiO₂ film to etch | SiO₂ film to etch |
| Type | rate of SiN film | rate of Si film |
| Related Example | 0.7 | 3.61 |
| Experimental Example | 0.93 | 5.63 |

Referring to Table 3, as compared with Related Example, both the etch rate of the SiO₂ film and the etch rate of the SiN film are reduced in Experimental Example. However, the extent of the reduction in the etch rate of the SiN film is greater than the extent of the reduction in the etch rate of the SiO₂ film. Referring to Table 3, the ratio of the etch rate of the SiO₂ film to the etch rate of the SiN film is greater in Experimental Example than that in Related Example. From the above results, it may be seen that the difference between the etch rate of the SiO₂ film and the etch rate of the SiN film is reduced in Experimental Example as compared with that in Related Example.

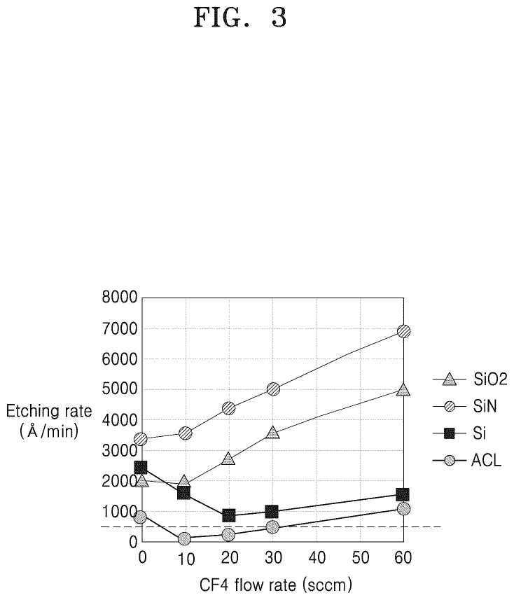

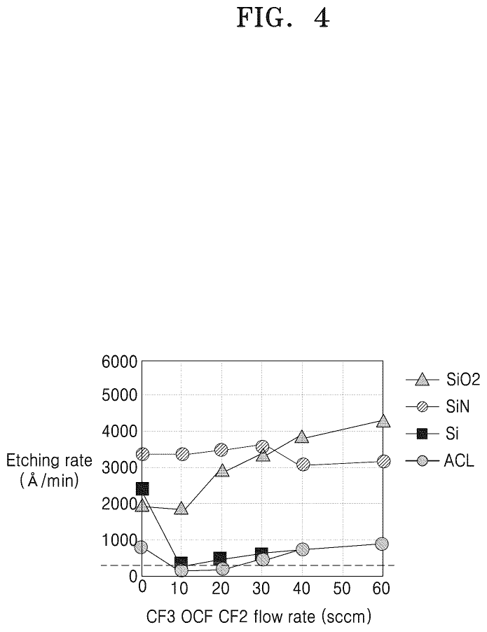

FIG. 3 is a diagram illustrating graphs of the etch rate of each of the SiO₂ film, the SiN film, the Si film, and the ACL according to the flow rate of CF₄ gas in Related Example. FIG. 4 is a diagram illustrating graphs of the etch rate of each of the SiO₂ film, the SiN film, the Si film, and the ACL according to the flow rate of CF₃OCFCF₂ gas in Experimental Example.

Referring to FIG. 3, the etch rate of each of the SiO₂ film, the SiN film, the Si film, and the ACL depending on the flow rate of CF₄ gas in Related Example is shown. Experimental conditions in Related Example are the same as shown in Table 1 except that the flow rate of CF₄ gas was changed to 0 sccm, 10 sccm, 20 sccm, 30 sccm, or 60 sccm. FIG. 3 illustrates that both the SiO₂ film and the SiN film have etch rates (A/min) increasing with the increasing flow rate of CF₄ gas. Therefore, the difference between the etch rate of the SiO₂ film and the etch rate of the SiN film does not significantly vary depending on the flow rate of CF₄ gas.

Referring to FIG. 4, the etch rate of each of the SiO₂ film, the SiN film, the Si film, and the ACL depending on the flow rate of CF₄ gas in Experimental Example is shown. Experimental conditions in Experimental Example are the same as shown in Table 1 except that the flow rate of CF₃OCFCF₂ gas was changed to 0 sccm, 10 sccm, 20 sccm, 30 sccm, 40 sccm, or 60 sccm. In FIG. 4, it may be seen that the difference between the etch rate of the SiO₂ film and the etch rate of the SiN film is reduced when the flow rate of CF₃OCFCF₂ gas is 20 sccm, 30 sccm, and 40 sccm. From the above experimental results, FIG. 4 illustrates that, when the sum of respective flow rates of gases (CF₄, H₂, CH₂F₂, and Cl₂) except for CF₃OCFCF₂ is assumed to be 100 and the flow rate of CF₃OCFCF₂ has a ratio of 100:20 to 100:40, the difference between the etch rate of the SiO₂ film and the etch rate of the SiN film is significantly reduced compared to the related example in FIG. 3.

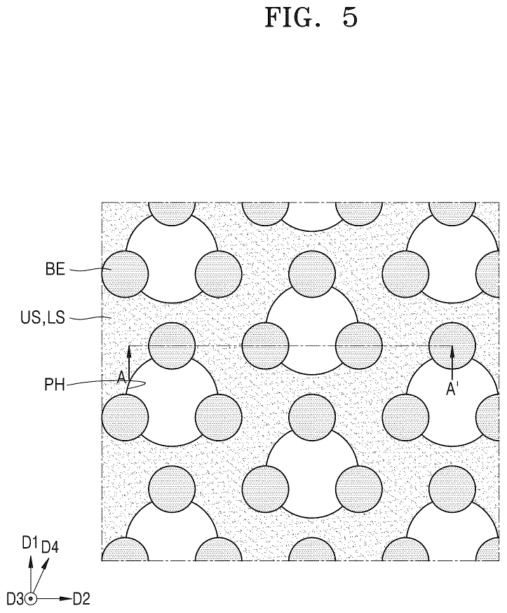

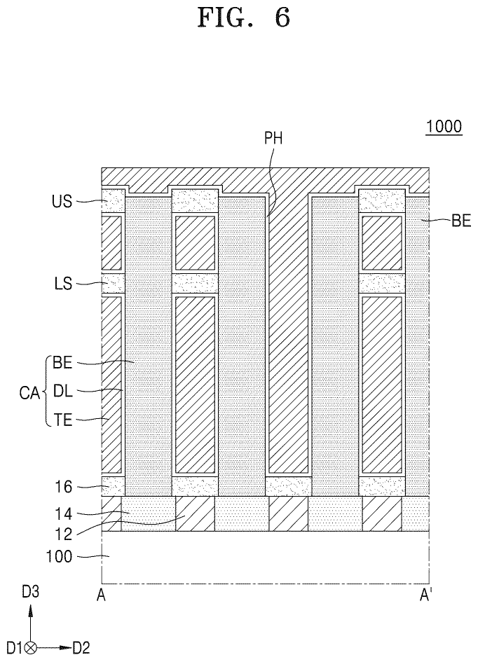

FIG. 5 is a plan view illustrating a semiconductor device according to one or more embodiments. FIG. 6 is a cross-sectional view of the semiconductor device of FIG. 5, taken along a line A-A′ of FIG. 5.

Referring to FIGS. 5 and 6, a semiconductor device 1000 may include a second substrate 100, a first insulating pattern 12, a conductive contact 14, an etch stop pattern 16, a capacitor CA, a lower support pattern LS, and an upper support pattern US. The capacitor CA may include a lower electrode BE, a dielectric film DL, and an upper electrode TE.

The second substrate 100 may be provided. The second substrate 100 may correspond to the semiconductor structure SST in FIGS. 2A to 2D. The second substrate 100 may include a semiconductor substrate. However, embodiments are not limited thereto. For example, the second substrate 100 may have a device structure of DRAM. Therefore, the semiconductor device 1000 may include a DRAM device.

The first insulating pattern 12 may be arranged on the second substrate 100. The first insulating pattern 12 may be provided on and cover a portion of an upper surface of the second substrate 100. For example, the first insulating pattern 12 may include at least one of silicon nitride, silicon oxide, or silicon oxynitride. As another example, the first insulating pattern 12 may include an empty region.

It should be understood that the terms such as “first”, “second”, and “third” may be used herein only to distinguish components from each other and do not indicate manufacturing sequences between the components or positional features thereof.

The conductive contact 14 may be arranged on the second substrate 100. A plurality of conductive contacts 14 may be provided and may be spaced apart from each other in a first horizontal direction D1 and a second horizontal direction D2. The plurality of conductive contacts 14 may be spaced apart from each other with the first insulating pattern 12 therebetween. In FIGS. 5 to 14, the first horizontal direction D1 and the second horizontal direction D2 may be directions that are parallel to the upper surface of the second substrate 100 and intersect with (for example, are orthogonal to) each other. A vertical direction D3 may be a direction that is perpendicular to the upper surface of the second substrate 100.

The conductive contact 14 may include at least one of an impurity-doped semiconductor material (for example, polycrystalline silicon), a metal-semiconductor compound (for example, tungsten silicide), a conductive metal nitride (for example, titanium nitride, tantalum nitride, tungsten nitride, or the like), or a metal (for example, titanium, tungsten, tantalum, or the like). The conductive contact 14 may be electrically connected to an impurity region (for example, source/drain terminals) formed in the second substrate 100.

The etch stop pattern 16 may be arranged on the first insulating pattern 12. The etch stop pattern 16 may be provided on and cover the first insulating pattern 12 and may expose the conductive contacts 14. The etch stop pattern 16 may include at least one of silicon oxide, silicon carbon nitride (SiCN), or silicon boron nitride (SiBN).

The lower electrode BE may be arranged on the conductive contact 14. The lower electrode BE may be connected to the conductive contact 14. The lower electrode BE may extend in the vertical direction D3. The vertical direction D3 may be a direction that is perpendicular to the upper surface of the second substrate 100. The lower electrode BE may have a pillar shape. A plurality of lower electrodes BE may be provided and may be spaced apart from each other in the first horizontal direction D1 and the second horizontal direction D2. For example, the lower electrodes BE may be arranged in a honeycomb shape in a plan view. For example, one lower electrode BE may be centered, and six lower electrodes BE may be arranged adjacent to and to hexagonally surround the one lower electrode BE.

The lower electrode BE may include a conductive material. For example, the lower electrode BE may include at least one of silicon (Si), metal materials (for example, cobalt, titanium, nickel, tungsten, and molybdenum), metal nitrides (for example, titanium nitride (TiN), titanium silicon nitride (TiSiN), titanium aluminum nitride (TiAlN), tantalum nitride (TaN and TaAlN), and tungsten nitride (WN)), noble metals (for example, platinum (Pt), ruthenium (Ru), and iridium (Ir)), conductive oxides (PtO, RuO₂, IrO₂, SrRuO₃ (SRO), (Ba,Sr) RuO₃ (BSRO), CaRuO₃ (CRO), and LSCo), or metal silicides.

The upper support pattern US and the lower support pattern LS may be provided on the second substrate 100. The upper support pattern US and the lower support pattern LS may be spaced apart from each other in the vertical direction D3. The upper support pattern US may be located higher than the lower support pattern LS. Support patterns spaced apart from each other in the vertical direction D3 may be further provided, and a support pattern in the uppermost layer may be referred to as the upper support pattern US. For example, support patterns arranged in three layers to be apart from each other in the vertical direction D3 may be provided, and a support pattern in the uppermost layer from among the support patterns in three layers may be referred to as the upper support pattern US. The upper support pattern US and the lower support pattern LS may be provided between adjacent lower electrodes BE. The upper support pattern US and the lower support pattern LS may be in contact with a side surface of the lower electrode BE and may be provided on and surround the side surface of the lower electrode BE. The upper support pattern US and the lower support pattern LS may physically support the lower electrode BE. The thickness of the upper support pattern US in the vertical direction D3 may be different from the thickness of the lower support pattern LS in the vertical direction D3. Each of the upper support pattern US and the lower support pattern LS may include, for example, at least one of silicon nitride, SiBN, or SiCN.

A through-hole PH may be arranged between adjacent lower electrodes BE. For example, the through-hole PH may be arranged with a circular shape between three lower electrodes BE adjacent to each other and may expose a portion of the side surface of each of the three lower electrodes BE as illustrated in FIG. 5. However, embodiments are not limited thereto, and the through-hole PH may be arranged with various shapes between a plurality of lower electrodes BE. The through-hole PH may pass through the upper support pattern US and the lower support pattern LS. The through-hole PH may expose the etch stop pattern 16. A plurality of through-holes PH may be provided and may be spaced apart from each other in the first horizontal direction D1 and the second horizontal direction D2.

The dielectric film DL may be provided on the upper support pattern US, the lower support pattern LS, the lower electrode BE, and the etch stop pattern 16. The dielectric film DL may be provided on and conformally cover the upper support pattern US, the lower support pattern LS, the lower electrode BE, and the etch stop pattern 16. The dielectric film DL may be in contact with the upper surface of the lower electrode BE. The dielectric film DL may fill portions of the through-holes PH. The dielectric film DL, which is in contact with the lower electrode BE, may have the same crystal structure as the crystal structure of the lower electrode BE. For example, the dielectric film DL may have a tetragonal structure. The dielectric film DL may include a single film of one selected from, for example, combinations of metal oxides, such as hafnium oxide (HfO₂), zirconium oxide (ZrO₂), aluminum oxide (Al₂O₃), lanthanum oxide (La₂O₃), tantalum oxide (Ta₂O₃), and titanium oxide (TiO₂), and perovskite-structure dielectric materials, such as strontium tin oxide (SrTiO₃) (STO), (barium (Ba), strontium (Sr)) TiO₃ (BST), BaTiO₃, lead zirconate titanate (PZT), and lead lanthanum zirconate titanate (PLZT), or may include a combination of films of these materials.

The upper electrode TE may be provided on the dielectric film DL. The upper electrode TE may cover the lower electrode BE, the upper support pattern US, and the lower support pattern LS. The upper electrode TE may fill the remaining portions of the through-holes PH, a space between the upper support pattern US and the lower support pattern LS, and a space between the lower support pattern LS and the etch stop pattern 16. The dielectric film DL may be arranged between the lower electrode BE and the upper electrode TE, between the upper support pattern US and the upper electrode TE, and between the lower support pattern LS and the upper electrode TE. The dielectric film DL may be arranged between the upper surface of the lower electrode BE and the upper electrode TE.

The upper electrode TE may include at least one of titanium nitride, impurity-doped polysilicon, or impurity-doped silicon-germanium. The upper electrode TE may include a single film or multiple films. The lower electrode BE, the dielectric film DL, and the upper electrode TE may be included in the capacitor CA. For example, the capacitor CA may operate as an information storage element for the semiconductor device 1000 according to one or more embodiments to operate as a memory device.

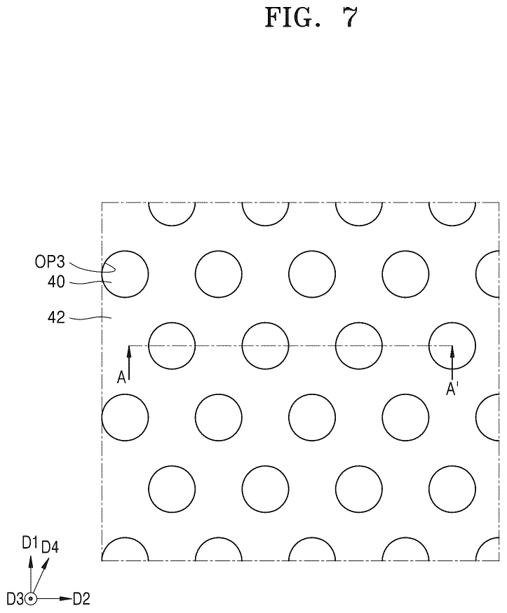

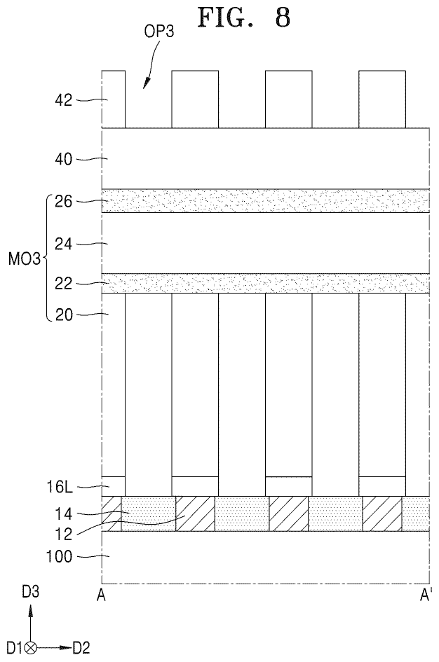

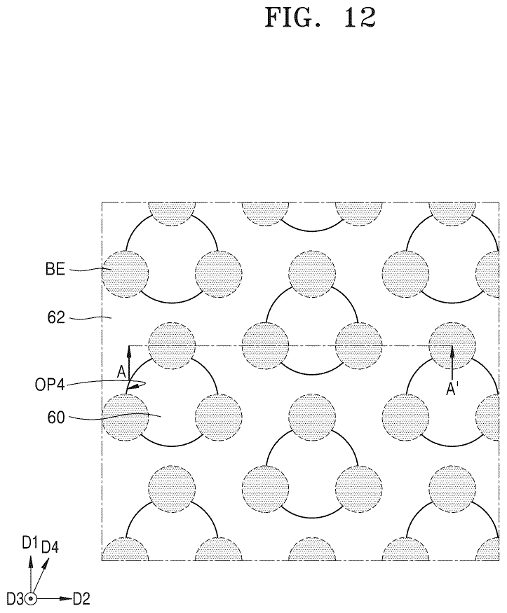

FIGS. 7 to 14 are diagrams illustrating a method of manufacturing the semiconductor device 1000 of FIG. 6, and in particular, FIGS. 7 and 12 are plan views illustrating the method of manufacturing the semiconductor device 1000 of FIG. 6, and FIGS. 8 to 11, 13, and 14 are cross-sectional views illustrating the method of manufacturing the semiconductor device 1000 of FIG. 6. The method of manufacturing the semiconductor device 1000 of FIG. 6 is described below with reference to FIGS. 7 to 14. For simplicity of description, repeated descriptions given above are omitted.

Referring to FIGS. 7 and 8, the second substrate 100 may be provided. The first insulating pattern 12 may be formed on the second substrate 100. The conductive contact 14 may be formed in the first insulating pattern 12. An etch stop film 16L may be formed over the second substrate 100. The etch stop film 16L may be formed to cover the upper surface of the first insulating pattern 12 and the upper surface of the conductive contact 14.

A third mold structure MO3 may be formed on the etch stop film 16L. The third mold structure MO3 may be formed by alternately stacking insulating materials of several types. For example, the third mold structure MO3 may be formed by stacking a first mold film 20, a lower support film 22, a second mold film 24, and an upper support film 26 in the stated order. The lower support film 22 may include a material having etch selectivity to the first mold film 20. The upper support film 26 may include a material having etch selectivity to the second mold film 24. The first mold film 20 and the second mold film 24 may include the same material. For example, the first mold film 20 and the second mold film 24 may each include silicon oxide. The lower support film 22 and the upper support film 26 may include the same material. For example, the lower support film 22 and the upper support film 26 may each include at least one of silicon nitride, SiBN, or SiCN.

A first mask film 40 and a second mask pattern 42 may be formed in the stated order on the third mold structure MO3. The first mask film 40 may cover the upper support film 26. The first mask film 40 may include, for example, at least one of polysilicon, silicon nitride, or silicon oxynitride. The second mask pattern 42 may be formed on the first mask film 40 and may have a third opening OP3. A plurality of third openings OP3 may be provided, and a portion of an upper surface of the first mask film 40 may be exposed by the third opening OP3. The third opening OP3 may vertically overlap the conductive contact 14. The second mask pattern 42 may include, for example, at least one of a spin-on-hardmask (SOH), an ACL, or polycrystalline silicon.

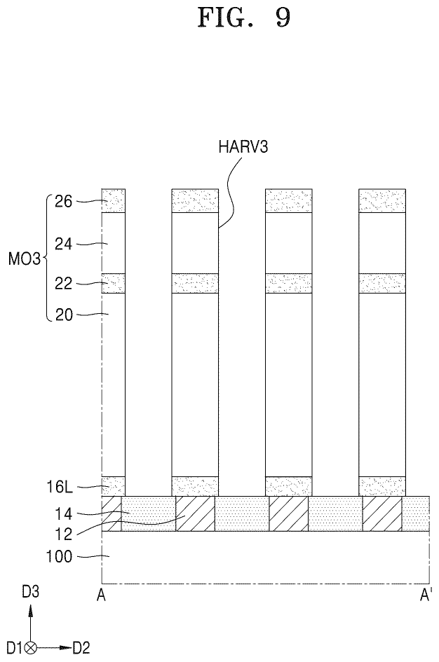

Referring to FIG. 9, an etching process may be performed on the first mask film 40, the third mold structure MO3, and the etch stop film 16L by using the second mask pattern 42 as an etch mask. The etching process may use a low-temperature plasma etching process. The etching process may be performed in the same manner as the etching process using a low-temperature plasma etching process and having been described with reference to FIGS. 1 to 2D. For example, the first etching gas used in the etching process may include CF₃OCFCF₂. For simplicity of description, descriptions of the etching process using a low-temperature plasma etching process and having been described with reference to FIGS. 1 to 2D are omitted.

Therefore, a third via hole HARV3 may be formed with the same shape as the third opening OP3 in a plan view. A plurality of third via holes HARV3 may be formed according to the third opening OP3. The third via hole HARV3 may pass through the third mold structure MO3 and the etch stop film 16L in the vertical direction D3 and may expose the upper surface of the conductive contact 14. After the etching process, a portion of the etch stop film 16L, which is not etched and remains, may be included in the etch stop pattern 16. For example, the first mask film 40 and the second mask pattern 42 may be removed by a separate removal process after the etching process.

The method of manufacturing a semiconductor device, according to one or more embodiments, may include forming, over the second substrate 100, the third mold structure MO3 that includes the first mold film 20, the lower support film 22, the second mold film 24, and the upper support film 26, forming the second mask pattern 42 on the third mold structure MO3, and performing a low-temperature plasma etching process by using the second mask pattern 42 as an etch mask. The first mold film 20 and the second mold film 24 may include the same material, and the lower support film 22 and the upper support film 26 may include the same material. For example, the first mold film 20 and the second mold film 24 may each include silicon oxide, and the lower support film 22 and the upper support film 26 may each include silicon nitride. For example, the third mold structure MO3 may have a structure in which different insulating materials are alternately stacked one-by-one, similar to the first mold structure MO1 in FIGS. 1 to 2D. In the low-temperature plasma etching process, the first etching gas described with reference to FIGS. 1 to 2D may be used. Therefore, the difference between the etch rate of each of the first mold film 20 and the second mold film 24 and the etch rate of each of the lower support film 22 and the upper support film 26 may be reduced. Due to this reduced difference, the degree of difficulty and cost in a method of forming the third via hole HARV3 may be reduced, and the degree of difficulty and cost in the method of manufacturing the semiconductor device 1000 may be reduced.

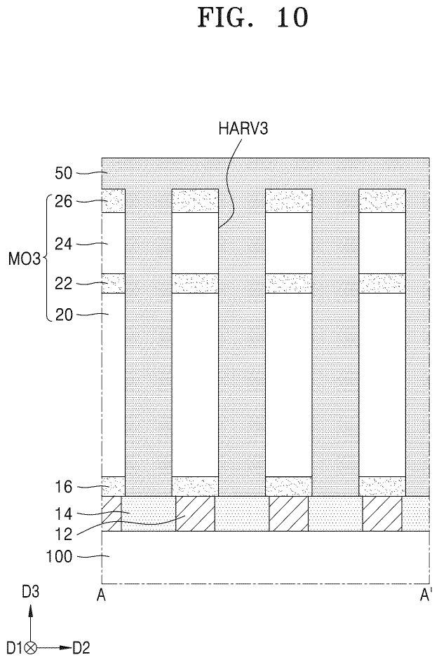

Referring to FIG. 10, a first lower electrode film 50 may be formed on the third mold structure MO3 and may fill the third via hole HARV3. The first lower electrode film 50 may cover the exposed upper surface of the conductive contact 14 and the upper support film 26. For example, the first lower electrode film 50 may be formed by a chemical vapor deposition (CVD) process or an atomic layer deposition (ALD) process.

The first lower electrode film 50 may include at least one of silicon (Si), metal materials (for example, cobalt, titanium, nickel, tungsten, and molybdenum), metal nitrides (for example, titanium nitride (TiN), titanium silicon nitride (TiSiN), titanium aluminum nitride (TiAlN), tantalum nitride (TaN and TaAlN), and tungsten nitride (WN)), noble metals (for example, platinum (Pt), ruthenium (Ru), and iridium (Ir)), conductive oxides (PtO, RuO₂, IrO₂, SrRuO₃ (SRO), (Ba,Sr) RuO₃ (BSRO), CaRuO₃ (CRO), and LSCo), or metal silicides.

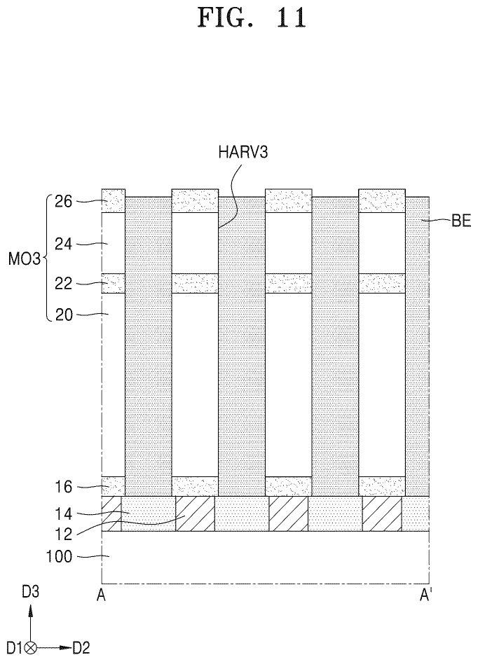

Referring to FIG. 11, an upper portion of the first lower electrode film 50 may be removed. The lower electrode BE may be formed from the first lower electrode film 50. Removing the upper portion of the first lower electrode film 50 may include, for example, performing an etch-back process. The lower electrode BE may pass through the third mold structure MO3 in the vertical direction D3 and may be electrically connected to the conductive contact 14. For example, the lower electrode BE may be formed with a pillar shape. An upper portion of the third via hole HARV3 may not be filled with the lower electrode BE.

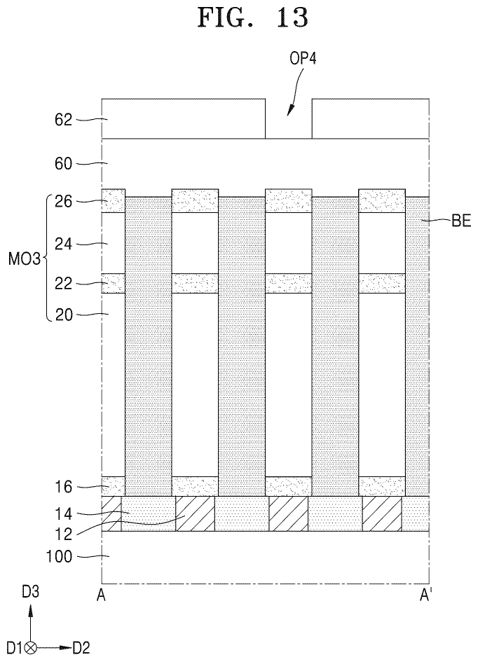

Referring to FIGS. 12 and 13, a second mask film 60 and a third mask pattern 62 may be formed in the stated order on the third mold structure MO3 and the lower electrode BE. The second mask film 60 may cover the upper support film 26 and the lower electrode BE. The third mask pattern 62 may be formed on the second mask film 60 and may have a fourth opening OP4. A plurality of fourth openings OP4 may be formed. A portion of an upper surface of the second mask film 60 may be exposed by the fourth opening OP4. The second mask film 60 may include, for example, polysilicon. The third mask pattern 62 may include, for example, a photoresist.

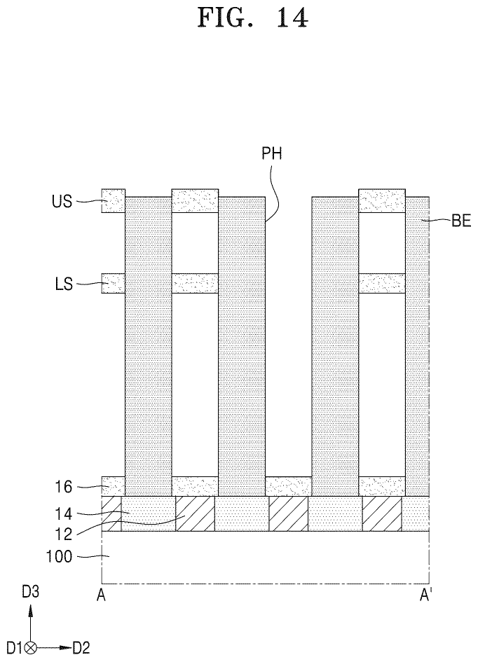

Referring to FIG. 14, the second mask film 60 and the upper support film 26 may be anisotropically etched by using the third mask pattern 62 as an etch mask. Accordingly, a portion of the second mask film 60 and a portion of the upper support film 26, which vertically overlap the fourth opening OP4, may be removed. The remaining portion of the upper support film 26 may form the upper support pattern US. The through-hole PH may be formed through the upper support pattern US. The through-hole PH may be formed in a plural number and may vertically overlap the fourth opening OP4. A portion of an upper surface of the second mold film 24 may be exposed by the through-hole PH.

Next, the second mold film 24 may be removed. Accordingly, a lower surface of the upper support pattern US, a portion of the side surface of the lower electrode BE, and an upper surface of the lower support film 22 may be exposed. A process of removing the second mold film 24 may include an isotropic etching process. To perform the isotropic etching process, phosphoric acid (H₃PO4) may be used. For example, the remaining portion of the second mask film 60 may be removed before the second mold film 24 is removed, but embodiments are not limited thereto. By removing the second mold film 24, the through-hole PH may extend to the upper surface of the lower support film 22.

A portion of the lower support film 22, which vertically overlaps the through-hole PH, may be etched, and a portion of an upper surface of the first mold film 20. The remaining portion of the lower support film 22 may be included in the lower support pattern LS. The through-hole PH may extend into the lower support pattern LS and may further pass through the lower support pattern LS.

Next, the first mold film 20 may be removed. Accordingly, the lower surface of the lower support pattern LS, the remaining portion of the side surface of the lower electrode BE, and the upper surface of the etch stop pattern 16 may be exposed. A process of removing the first mold film 20 may include an isotropic etching process. To perform the isotropic etching process, phosphoric acid (H₃PO4) may be used.

Referring again to FIG. 6, the dielectric film DL may be formed on the upper support pattern US, the lower support pattern LS, the lower electrode BE, and the etch stop pattern 16. The dielectric film DL may conformally cover the upper support pattern US, the lower support pattern LS, the lower electrode BE, and the etch stop pattern 16. The dielectric film DL may fill a portion of the through-hole PH.

The dielectric film DL, which is in contact with the lower electrode BE, may have the same crystal structure as the crystal structure of the lower electrode BE. For example, the dielectric film DL may have a tetragonal structure. The dielectric film DL may be formed by a deposition technique having excellent step coverage, such as CVD or ALD.

The upper electrode TE may be formed on the dielectric film DL. The upper electrode TE may fill the remaining portion of the through-hole PH and may cover the lower electrode BE. The upper electrode TE may fill a space between the lower electrode BE and an adjacent lower electrode BE, a space between the upper support pattern US and the lower support pattern LS, and a space between the lower support pattern LS and the etch stop pattern 16. By forming the upper electrode TE, the dielectric film DL may be arranged between the lower electrode BE and the upper electrode TE. The lower electrode BE, the dielectric film DL, and the upper electrode TE may be included in the capacitor CA.

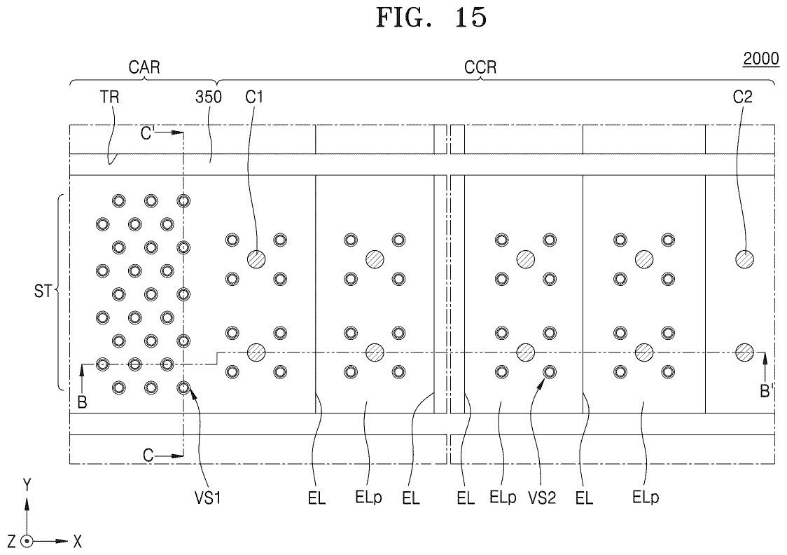

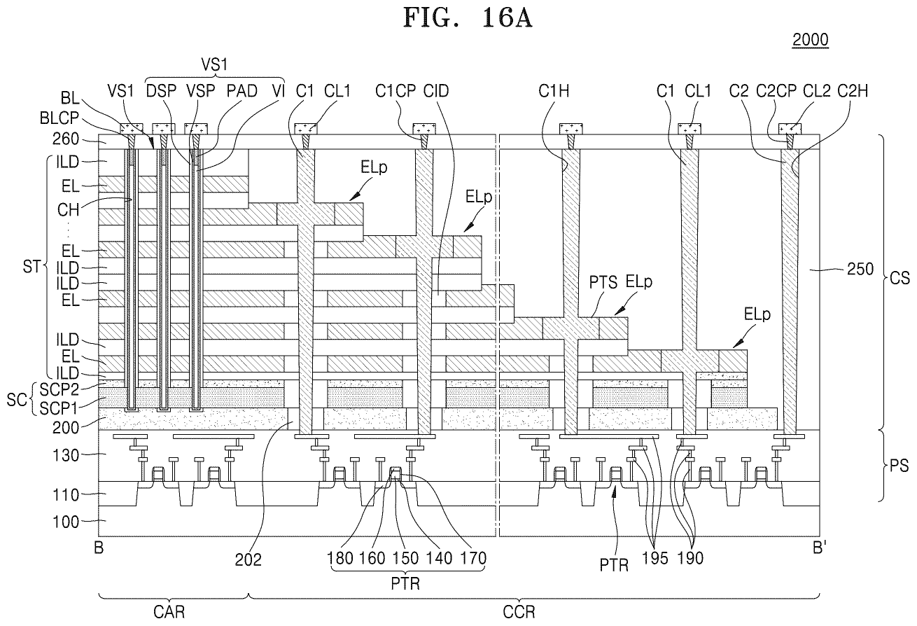

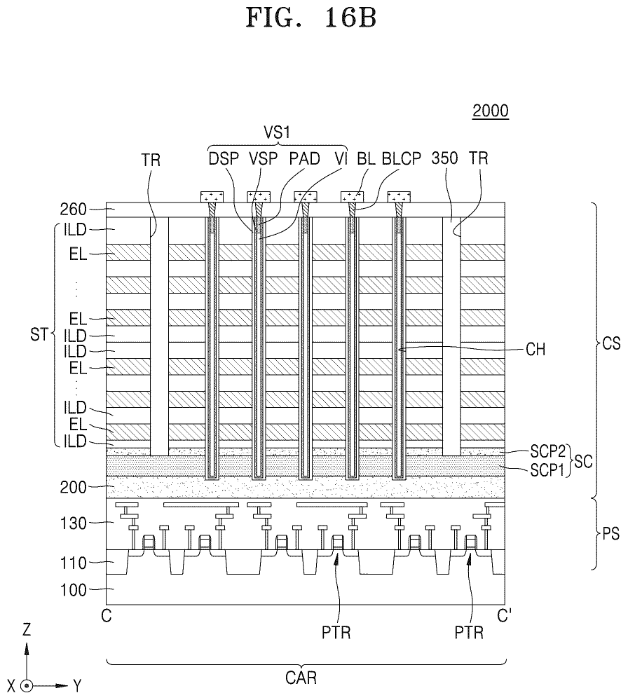

FIG. 15 is a plan view illustrating a semiconductor device according to one or more embodiments. FIG. 16A is a cross-sectional view of the semiconductor device of FIG. 15, taken along a line B-B′ of FIG. 15. FIG. 16B is a cross-sectional view of the semiconductor device of FIG. 15, taken along a line C-C′ of FIG. 15.

Referring to FIGS. 15, 16A, and 16B, a semiconductor device 2000 according to one or more embodiments may include a second substrate 100, a peripheral circuit structure PS on the second substrate 100, and a cell array structure CS on the peripheral circuit structure PS.

The second substrate 100 may include a cell array area CAR and a contact area CCR. In descriptions regarding FIGS. 15 to 16B, a first horizontal direction X is defined as a direction that is parallel to the upper surface of the second substrate 100, a second horizontal direction Y is defined as a direction that is parallel to the upper surface of the second substrate 100 and perpendicular to the first horizontal direction X, and a vertical direction Z is defined as a direction that is perpendicular to the upper surface of the second substrate 100.

The second substrate 100 may extend in the first horizontal direction X and the second horizontal direction Y from the cell array area CAR toward the contact area CCR. In a plan view, the contact area CCR may extend in the first horizontal direction X (or the opposite direction to the first horizontal direction X) from the cell array area CAR. However, embodiments are not limited thereto, and for example, the contact area CCR may extend in the second horizontal direction Y (or the opposite direction to the second horizontal direction Y) from the cell array area CAR.

The second substrate 100 may include, for example, a silicon substrate, a silicon-germanium substrate, a germanium substrate, or a monocrystalline epitaxial layer grown on a monocrystalline silicon substrate. A device isolation film 110 may be provided in the second substrate 100. The device isolation film 110 may define an active region of the second substrate 100. The device isolation film 110 may include, for example, silicon oxide.

The peripheral circuit structure PS may be provided on the second substrate 100. The peripheral circuit structure PS may include peripheral circuit transistors PTR on the active region of the second substrate 100, peripheral contact plugs 190, peripheral circuit wiring lines 195 electrically connected to the peripheral circuit transistors PTR via the peripheral contact plugs 190, and a peripheral circuit insulating film 130 provided on and surrounding the components set forth above.

The peripheral circuit transistors PTR, the peripheral contact plugs 190, and the peripheral circuit wiring lines 195 may be included in a peripheral circuit. The peripheral circuit transistors PTR may perform operations of the semiconductor device 2000. For example, each of the peripheral circuit transistors PTR may include a peripheral gate insulating film 140, a peripheral gate electrode 150, a peripheral capping pattern 160, a peripheral gate spacer 170, and peripheral source/drain regions 180.

The peripheral gate insulating film 140 may be provided between the peripheral gate electrode 150 and the second substrate 100. The peripheral capping pattern 160 may be provided on the peripheral gate electrode 150. The peripheral gate spacer 170 may be provided on and cover respective sidewalls of the peripheral gate insulating film 140, the peripheral gate electrode 150, and the peripheral capping pattern 160. The peripheral source/drain regions 180 may be respectively provided in inner portions of the second substrate 100, which are adjacent to both sides of the peripheral gate electrode 150.

The peripheral circuit wiring lines 195 may be electrically connected to the peripheral circuit transistors PTR via the peripheral contact plugs 190. Each of the peripheral circuit transistors PTR may include, for example, an N-channel metal-oxide-semiconductor (NMOS) transistor or a P-channel metal-oxide-semiconductor (PMOS) transistor. Each of the peripheral circuit transistors PTR may include a planar transistor or a gate-all-around transistor. For example, each of the peripheral contact plugs 190 may have an increasing width in the first horizontal direction X or the second horizontal direction Y away from the second substrate 100 in the vertical direction Z. The peripheral contact plugs 190 and the peripheral circuit wiring lines 195 may each include a conductive material, such as a metal.

The peripheral circuit insulating film 130 may be provided on the upper surface of the second substrate 100. The peripheral circuit insulating film 130 may be arranged on the second substrate 100 to be provided on and cover the peripheral circuit transistors PTR, the peripheral contact plugs 190, and the peripheral circuit wiring lines 195. The peripheral circuit insulating film 130 may include a plurality of insulating films having a multilayered structure. For example, the peripheral circuit insulating film 130 may include silicon oxide, silicon nitride, silicon oxynitride, and/or a low-k material.

The cell array structure CS may be provided on the peripheral circuit insulating film 130, the cell array structure CS including a third substrate 200 and a stack structure ST on the third substrate 200. The third substrate 200 may extend in the first horizontal direction X and the second horizontal direction Y. The third substrate 200 may not be provided in some portions of the contact area CCR. The third substrate 200 may include a semiconductor substrate including a semiconductor material. The third substrate 200 may include, for example, at least one of silicon (Si), germanium (Ge), silicon-germanium (SiGe), gallium arsenide (GaAs), indium gallium arsenide (InGaAs), aluminum gallium arsenide (AlGaAs), or a mixture thereof.

The stack structure ST may be provided over the third substrate 200. The stack structure ST may extend from the cell array area CAR to the contact area CCR. A plurality of stack structures ST may be provided, and the plurality of stack structures ST may be arranged in the second horizontal direction Y to be spaced apart from each other in the second horizontal direction Y with an isolation structure 350 therebetween. Hereinafter, although one stack structure ST is described for convenience of description, the following description may be equally applied to other stack structures ST.

The stack structure ST may include interlayer dielectrics ILD and gate electrodes EL, which are alternately stacked one-by-one. The thickness of each of the gate electrodes EL in the vertical direction Z may be substantially equal. Hereinafter, the thickness refers to a thickness in the vertical direction Z.

Each of the gate electrodes EL may have a decreasing length in the first horizontal direction X away from the third substrate 200 in the vertical direction Z. For example, in the first horizontal direction X, the length of each of the gate electrodes EL may be greater than the length of a gate electrode EL located directly thereabove. A lowermost gate electrode EL from among the gate electrodes EL of the stack structure ST may have the greatest length in the first horizontal direction X, and an uppermost gate electrode EL from among the gate electrodes EL may have the least length in the first horizontal direction X.

Each of the gate electrodes EL may have a pad portion ELp in the contact area CCR. The pad portions ELp of the gate electrodes EL may be respectively arranged at horizontally and vertically different positions. The pad portions ELp may form a stepped structure in the first horizontal direction X. The thickness of the pad portion ELp may be greater than the thicknesses of other portions of the gate electrode EL.

Due to the stepped structure, the stack structure ST may have a decreasing thickness in the vertical direction Z away from an outermost one of first vertical channel structures VS1 in the first horizontal direction X, and respective sidewalls of the gate electrodes EL may be apart at regular intervals in the first horizontal direction X, in a plan view.

The gate electrodes EL may each include, for example, at least one of a doped semiconductor (for example, doped silicon or the like), a metal (for example, tungsten, copper, aluminum, or the like), a conductive metal nitride (for example, titanium nitride, tantalum nitride, or the like), or a transition metal (for example, titanium, tantalum, or the like). More specifically, the gate electrodes EL may each include tungsten.

The interlayer dielectrics ILD may be respectively provided between the gate electrodes EL. For example, like the gate electrodes EL, each of the interlayer dielectrics ILD may have a decreasing length in the first horizontal direction X away from the third substrate 200 in the vertical direction Z.

For example, the thickness of each of the interlayer dielectrics ILD may be less than the thickness of each of the gate electrodes EL in the vertical direction Z. For example, the thickness of an uppermost one of the interlayer dielectrics ILD may be greater than the thickness of each of the other interlayer dielectrics ILD in the vertical direction Z. For example, the thickness of a lowermost one of the interlayer dielectrics ILD may be less than the thickness of each of the other interlayer dielectrics ILD in the vertical direction Z.

Except for the lowermost one of the interlayer dielectrics ILD and the uppermost one of the interlayer dielectrics ILD, the respective thicknesses of the other interlayer dielectrics ILD may be substantially equal in the vertical direction Z. However, embodiments are not limited thereto, and for example, the thicknesses of the interlayer dielectrics ILD may vary depending on characteristics of the semiconductor device 2000.

The interlayer dielectrics ILD may each include, for example, silicon oxide, silicon nitride, silicon oxynitride, and/or a low-k material. For example, the interlayer dielectrics ILD may each include a high-density plasma (HDP) oxide or tetraethylorthosilicate (TEOS).

In the cell array area CAR, a source structure SC may be provided between the third substrate 200 and the lowermost one of the interlayer dielectrics ILD. The source structure SC may extend from the cell array area CAR to the contact area CCR.

The source structure SC may include a first source conductive pattern SCP1 and a second source conductive pattern SCP2, which are stacked in the stated order on the third substrate 200. The second source conductive pattern SCP2 may be provided between the first source conductive pattern SCP1 and the lowermost one of the interlayer dielectrics ILD. The thickness of the first source conductive pattern SCP1 may be greater than the thickness of the second source conductive pattern SCP2 in the vertical direction Z.

The first and second source conductive patterns SCP1 and SCP2 may each include a semiconductor material, such as silicon, or an impurity-doped semiconductor material. When the first and second source conductive patterns SCP1 and SCP2 each include an impurity-doped semiconductor material, the impurity concentration of the first source conductive pattern SCP1 may be greater than the impurity concentration of the second source conductive pattern SCP2.

A plurality of first vertical channel structures VS1 may be provided in the cell array area CAR to pass through the stack structure ST and the source structure SC. The first vertical channel structures VS1 may each pass through at least a portion of the third substrate 200, and the lower surface of each of the first vertical channel structures VS1 may be at a level that is lower than those of the upper surface of the third substrate 200 and the lower surface of the source structure SC. For example, the first vertical channel structures VS1 may be in direct contact with the third substrate 200.

The first vertical channel structures VS1 may be arranged in zigzags in the first horizontal direction X or the second horizontal direction Y, in a plan view according to FIG. 15. The first vertical channel structures VS1 may not be provided in the contact area CCR.

The first vertical channel structures VS1 may be respectively provided in vertical channel holes CH that pass through the stack structure ST. The first vertical channel structures VS1 may each have a constant width in the first horizontal direction X or the second horizontal direction Y as the vertical direction Z increases. Alternatively, the first vertical channel structures VS1 may each have an increasing width in the first horizontal direction X or the second horizontal direction Y as the vertical direction Z increases.

Each of the first vertical channel structures VS1 may include a data storage pattern DSP and a vertical semiconductor pattern VSP that are provided in the stated order on an inner sidewall of a vertical channel hole CH, a buried insulating pattern VI that fills an inner space surrounded by the vertical semiconductor pattern VSP, and a conductive pad PAD on the buried insulating pattern VI. The conductive pad PAD may be provided in a space surrounded by the buried insulating pattern VI and the data storage pattern DSP (or the vertical semiconductor pattern VSP). The upper surface of each of the first vertical channel structures VS1 may have, for example, a circular shape, an elliptical shape, or a bar shape. The data storage pattern DSP may be adjacent to the sidewalls of the interlayer dielectrics ILD and the sidewalls of the gate electrodes EL. A barrier film may be arranged between the data storage pattern DSP and the gate electrode EL. The barrier film may include a metal oxide (for example, aluminum oxide (Al₂O₃)). The vertical semiconductor pattern VSP may conformally be provided on and cover an inner sidewall of the data storage pattern DSP.

The vertical semiconductor pattern VSP may be provided between the data storage pattern DSP and the buried insulating pattern VI. The vertical semiconductor pattern VSP may have a pipe or macaroni shape with a closed bottom. The data storage pattern DSP may have a pipe or macaroni shape with an open bottom.

The vertical semiconductor pattern VSP may include, for example, a semiconductor material doped with an impurity, an intrinsic semiconductor material doped with no impurity, or a polycrystalline semiconductor material. The vertical semiconductor pattern VSP may be in contact with a portion of the source structure SC. For example, the vertical semiconductor pattern VSP may be in contact with a first source conductive pattern SCP1 of the source structure SC. The conductive pad PAD may include, for example, an impurity-doped semiconductor material or a conductive material.

A plurality of second vertical channel structures VS2 may be provided in the contact area CCR to pass through a planarization insulating film 250, the stack structure ST, and the source structure SC. More specifically, the second vertical channel structures VS2 may respectively pass through the pad portions ELp of the gate electrodes EL. The second vertical channel structures VS2 may be respectively provided around first through-structures C1. The second vertical channel structures VS2 may not be provided in the cell array area CAR. The second vertical channel structures VS2 may be formed simultaneously with the first vertical channel structures VS1 and may have substantially identical structures to those of the first vertical channel structures VS1. However, the second vertical channel structures VS2 may not be provided depending on one or more embodiments.

The planarization insulating film 250 may be provided in the contact area CCR to partially be provided on and cover the stack structure ST and the peripheral circuit insulating film 130. For example, the planarization insulating film 250 may be provided on the pad portions ELp of the gate electrodes EL while covering the stepped structure of the stack structure ST. The planarization insulating film 250 may have an upper surface that is substantially flat. The upper surface of the planarization insulating film 250 may be substantially coplanar with the uppermost surface of the stack structure ST. For example, the upper surface of the planarization insulating film 250 may be substantially coplanar with the upper surface of the uppermost interlayer dielectric ILD from among the interlayer dielectrics ILD of the stack structure ST.

The planarization insulating film 250 may include one insulating film or a plurality of insulating films that are stacked. The planarization insulating film 250 may include, for example, an insulating material, such as silicon oxide, silicon nitride, silicon oxynitride, and/or a low-k material. The planarization insulating film 250 may include an insulating material that is different from those of the interlayer dielectrics ILD of the stack structure ST. For example, when the interlayer dielectrics ILD of the stack structure ST each include an HDP oxide, the planarization insulating film 250 may include TEOS.

Each of the first through-structures C1 may be provided in a first through-structure hole C1H that passes through the planarization insulating film 250, the stack structure ST, the source structure SC, and the third substrate 200. Each of the first through-structures C1 may be in direct contact with one of the pad portions ELp of the gate electrodes EL. Each of the first through-structures C1 may have a protrusion PTS at the same level as one of the pad portions ELp of the gate electrodes EL. The protrusion PTS may be a portion protruding in the first horizontal direction X or the second horizontal direction Y from the center of the first through-structure C1.

The first through-structures C1 may be respectively connected to the peripheral circuit wiring lines 195 of the peripheral circuit structure PS. The first through-structures C1 may be respectively and electrically connected to the peripheral circuit transistors PTR via the peripheral circuit wiring lines 195 and the peripheral contact plugs 190.

The first through-structures C1 may be respectively adjacent to the plurality of vertical channel structures VS2 and may be spaced apart from each other in a horizontal direction (the first horizontal direction X or the second horizontal direction Y). The first through-structures C1 may be spaced apart from the isolation structure 350 in the second horizontal direction Y.

A first sidewall insulating pattern 202 may be arranged between each of the first through-structures C1 and the third substrate 200. The first sidewall insulating pattern 202 may electrically insulate each of the first through-structures C1 from the third substrate 200. The first sidewall insulating pattern 202 may include silicon oxide, silicon nitride, silicon oxynitride, or a combination thereof.

Except for one gate electrode EL that is in direct contact with the first through-structure C1, a second sidewall insulating pattern CID may be arranged between each of the remaining gate electrodes EL and the first through-structure C1. The second sidewall insulating pattern CID may electrically insulate the first through-structure C1 from each of the remaining gate electrodes EL. The second sidewall insulating pattern CID may also be arranged between the source structure SC and the first through-structure C1. The second sidewall insulating pattern CID may electrically insulate the source structure SC from the first through-structure C1. The second sidewall insulating pattern CID may include silicon oxide, silicon nitride, silicon oxynitride, or a combination thereof.

A second through-structure C2 may be provided in a second through-structure hole C2H that passes through the planarization insulating film 250 and at least a portion of the peripheral circuit insulating film 130. The second through-structure C2 may be electrically connected to the peripheral circuit transistors PTR of the peripheral circuit structure PS. However, embodiments are not limited thereto, and for example, a plurality of second through-structures C2 may be provided. The second through-structure C2 may be spaced apart from the third substrate 200, the source structure SC, and the stack structure ST in the first horizontal direction X. The second through-structure C2 may be spaced apart from the isolation structure 350.

All the respective upper surfaces of the first vertical channel structures VS1, the second vertical channel structures VS2, the first through-structures C1, and the second through-structure C2 may be coplanar with each other.

An upper insulating film 260 may be provided on the planarization insulating film 250 and the stack structure ST. The upper insulating film 260 may be provided on and cover the upper surface of the planarization insulating film 250, the upper surface of the uppermost interlayer dielectric ILD from among the interlayer dielectrics ILD of the stack structure ST, and the upper surfaces of the first and second vertical channel structures VS1 and VS2.

The upper insulating film 260 may include one insulating film or a plurality of insulating films that are stacked. The upper insulating film 260 may include, for example, silicon oxide, silicon nitride, silicon oxynitride, and/or a low-k material. For example, the upper insulating film 260 may include an insulating material that is substantially identical to a material of the planarization insulating film 250 and may include a different insulating material from material of the interlayer dielectrics ILD of the stack structure ST.

Bit line contact plugs BLCP may be provided, the bit line contact plugs BLCP passing through the upper insulating film 260 and being respectively connected to the first vertical channel structures VS1 corresponding thereto. First contact plugs C1CP may be provided, the first contact plugs C1CP passing through the upper insulating film 260 and being respectively connected to the first through-structures C1 corresponding thereto. A second contact plug C2CP may be provided, the second contact plug C2CP passing through the upper insulating film 260 and being connected to the second through-structure C2.

Bit lines BL may be provided on the upper insulating film 260, the bit lines BL being respectively connected to the bit line contact plugs BLCP corresponding thereto. First conductive lines CL1, which are respectively connected to the first through-structures C1 corresponding thereto, and a second conductive line CL2, which is connected to the second through-structure C2, may be provided on the upper insulating film 260.

The bit line contact plugs BLCP, the first through-structures C1, the second through-structure C2, the bit lines BL, the first contact plugs C1CP, the second contact plug C2CP, and the first and second conductive lines CL1 and CL2 may each include, for example, a conductive material, such as a metal. Additional wiring lines and additional vias may be further provided on the upper insulating film 260 to be electrically connected to the bit lines BL and the first and second conductive lines CL1 and CL2.

When a plurality of stack structures ST are provided, the isolation structure 350 may be provided in anisolation trench TR crossing between the plurality of stack structures ST in the first horizontal direction X. The isolation structure 350 may be spaced apart from the first and second vertical channel structures VS1 and VS2 in the second horizontal direction Y.

The isolation structure 350 may pass through the stack structure ST and the second source conductive pattern SCP2. A vertical level of the upper surface of the isolation structure 350 may be substantially equal to vertical levels of the upper surfaces of the first and second vertical channel structures VS1 and VS2 and the first and second through-structures C1 and C2. For example, the lower surface of the isolation structure 350 may be substantially coplanar with the lower surface of the second source conductive pattern SCP2 and may be at a higher level than the upper surface of the third substrate 200 in the vertical direction Z.

A plurality of isolation structures 350 may be provided and may be spaced apart from each other in the second horizontal direction Y with the stack structure ST therebetween.

The isolation structure 350 may conformally be provided on and cover the respective sidewalls of the interlayer dielectrics ILD and the gate electrodes EL. The isolation structure 350 may include, for example, silicon oxide.

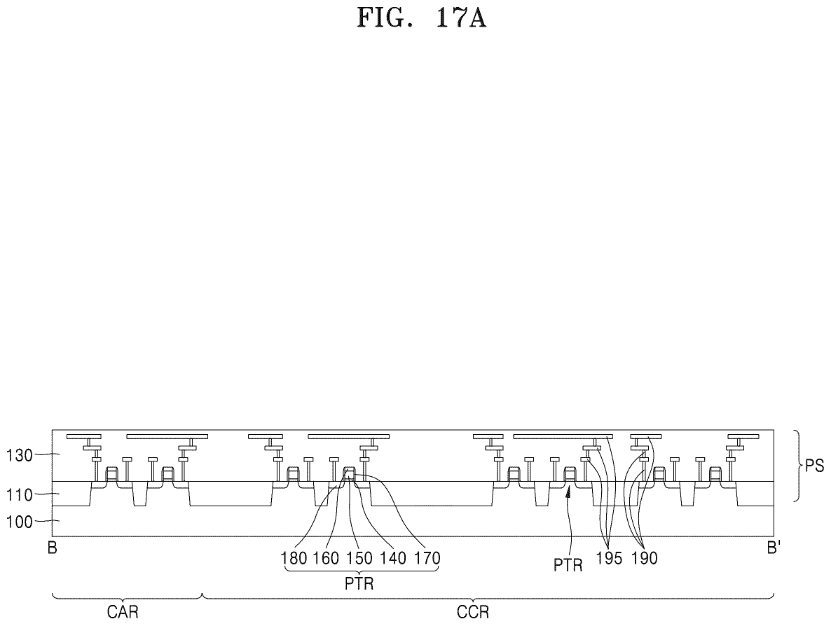

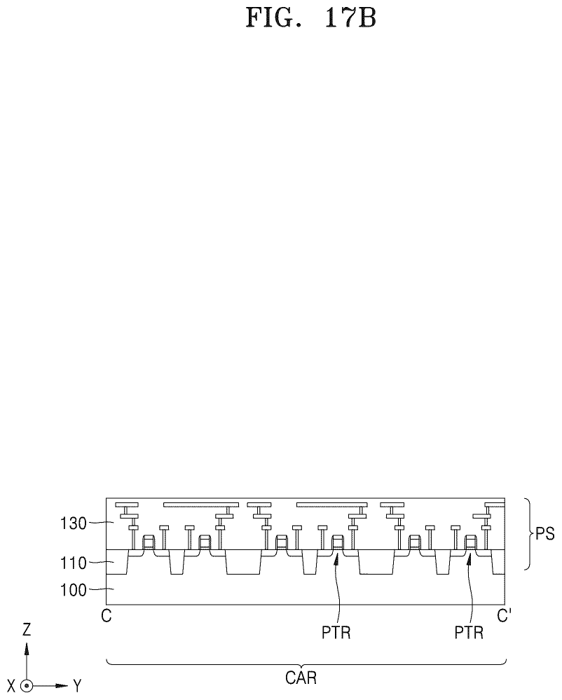

FIGS. 17A to 19B are diagrams illustrating a method of manufacturing a semiconductor device, according to one or more embodiments, and in particular, FIGS. 17A, 18A, and 19A are cross-sectional views taken along the line B-B′ of FIG. 15, and FIGS. 17B, 18B, and 19B are cross-sectional views taken along the line C-C′ of FIG. 15.

Referring to FIGS. 17A and 17B, the second substrate 100 including the cell array area CAR and the contact area CCR may be provided. The device isolation film 110 may be formed in the second substrate 100 to define an active region. The device isolation film 110 may be formed by forming a trench in an upper portion of the second substrate 100 and filling the trench with silicon oxide.

The peripheral circuit transistors PTR may be formed on the active region defined by the device isolation film 110. The peripheral contact plugs 190 and the peripheral circuit wiring lines 195 may be formed to be connected to the peripheral source/drain regions 180 of the peripheral circuit transistors PTR. The peripheral circuit insulating film 130 may be formed to be provided on and cover the peripheral circuit transistors PTR, the peripheral contact plugs 190, and the peripheral circuit wiring lines 195.

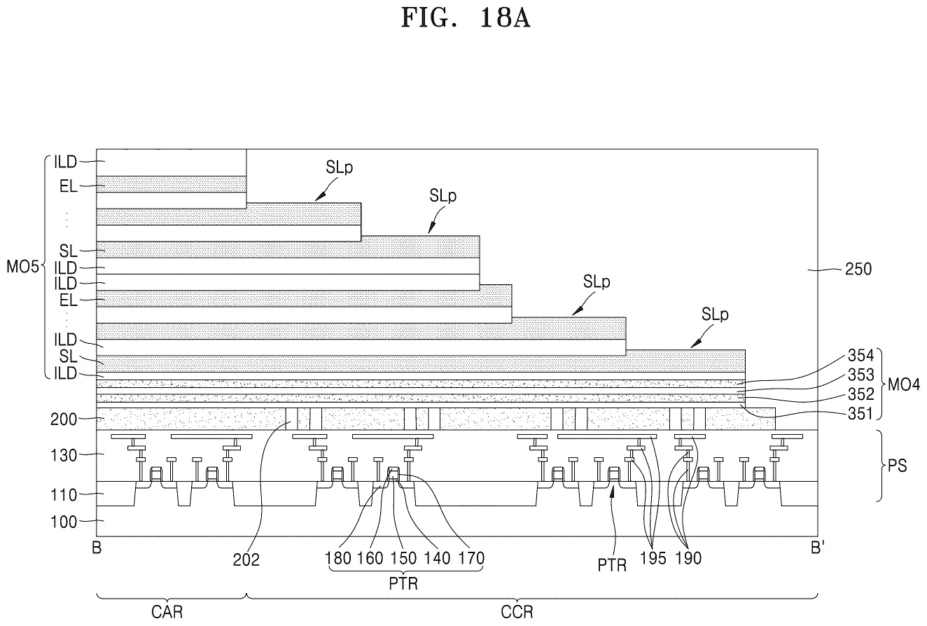

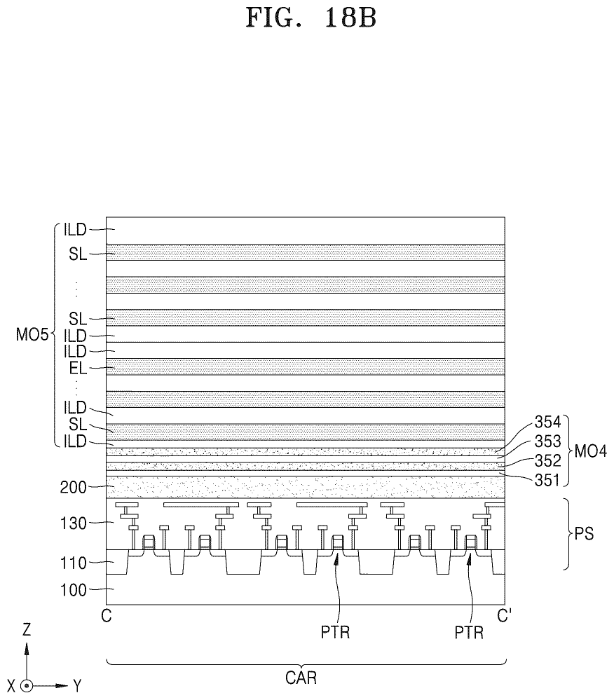

Referring to FIGS. 18A and 18B, the third substrate 200 may be formed on the peripheral circuit insulating film 130. The third substrate 200 may extend from the cell array area CAR toward the contact area CCR.

A portion of the third substrate 200 in the contact area CCR may be removed. Removing of the portion of the third substrate 200 may refer to making a space in which the second through-structure C2 is to be provided.

The first sidewall insulating pattern 202 may be formed in the third substrate 200. The first sidewall insulating pattern 202 may define a space in which the first through-structure C1 described below is to be formed.

A fourth mold structure MO4 may be formed on the third substrate 200. Forming the fourth mold structure MO4 may include stacking a first buffer insulating film 351, a first semiconductor film 352, a second buffer insulating film 353, and a second semiconductor film 354 in the stated order on the third substrate 200. The first and second buffer insulating films 351 and 353 may each include, for example, silicon oxide. The first and second semiconductor films 352 and 354 may each include, for example, a semiconductor material, such as silicon.

A fifth mold structure MO5 may be formed on the fourth mold structure MO4. Forming the fifth mold structure MO5 may include alternately stacking the interlayer dielectrics ILD and the sacrificial films SL one-by-one over the third substrate 200.

The third substrate 200 may be externally exposed by the vertical channel holes CH. The lower surfaces of the vertical channel holes CH may each be at a lower level than the upper surface of the third substrate 200.

Each of the sacrificial films SL may include a different insulating material from each of the interlayer dielectrics ILD. Each of the sacrificial films SL may include a material having etch selectivity to each of the interlayer dielectrics ILD. For example, the sacrificial films SL may each include silicon nitride and the interlayer dielectrics ILD may each include silicon oxide. Each of the sacrificial films SL may have a substantially equal thickness, and some of the interlayer dielectrics ILD may have different thicknesses from other interlayer dielectrics ILD in the vertical direction Z. The fifth mold structure MO5 may be similar to the first mold structure MO1 described with reference to FIGS. 1 to 2D, in that the fifth mold structure MO5 has a structure in which different insulating films (that is, the interlayer dielectrics ILD and the sacrificial films SL) are alternately stacked one-by-one.

A trimming process may be performed on the fifth mold structure MO5 to remove a portion of the fifth mold structure MO5 in the contact area CCR. The trimming process may include forming a mask pattern to cover a portion of the upper surface of the fifth mold structure MO5 in the cell array area CAR and the contact area CCR, patterning the fifth mold structure MO5 through the mask pattern, reducing the area of the mask pattern, and patterning the fifth mold structure MO5 through the mask pattern having a reduced area. The reducing of the area of the mask pattern and the patterning of the fifth mold structure MO5 through the mask pattern may be alternately repeated. By the trimming process, the fifth mold structure MO5 may have a stepped structure.

After the trimming process is performed, a preliminary pad portion SLp may be formed to a thickness that is greater than those of other portions of each of the sacrificial films SL in the vertical direction Z. The preliminary pad portion SLp is a portion of each of the sacrificial films SL and may be formed at an end of each of the sacrificial films SL. The preliminary pad portion SLp may be formed by removing respective portions of the interlayer dielectrics ILD that are externally exposed in the stepped structure, additionally depositing the same material as the sacrificial films SL, and etching the additionally deposited material such that the additionally deposited material remains only on the interlayer dielectrics ILD. Accordingly, the upper surface of the preliminary pad portion SLp may be at a higher level than the upper surface of the other portion of each of the sacrificial films SL, which is connected to the preliminary pad portion SLp.

The planarization insulating film 250 may be formed on the fifth mold structure MO5. The planarization insulating film 250 may be provided on and surround the fifth mold structure MO5. The planarization insulating film 250 may be provided on and cover a side surface of the fourth mold structure MO4, the side surface and a portion of the upper surface of the third substrate 200, and a portion of the upper surface of the peripheral circuit insulating film 130. The planarization insulating film 250 may be provided on and cover the preliminary pad portions SLp of the fifth mold structure MO5.

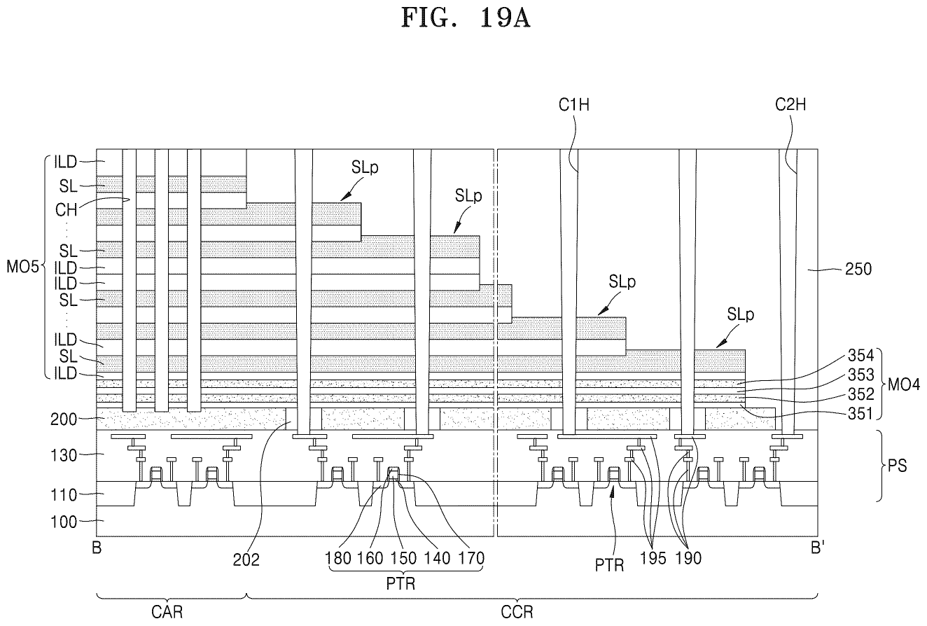

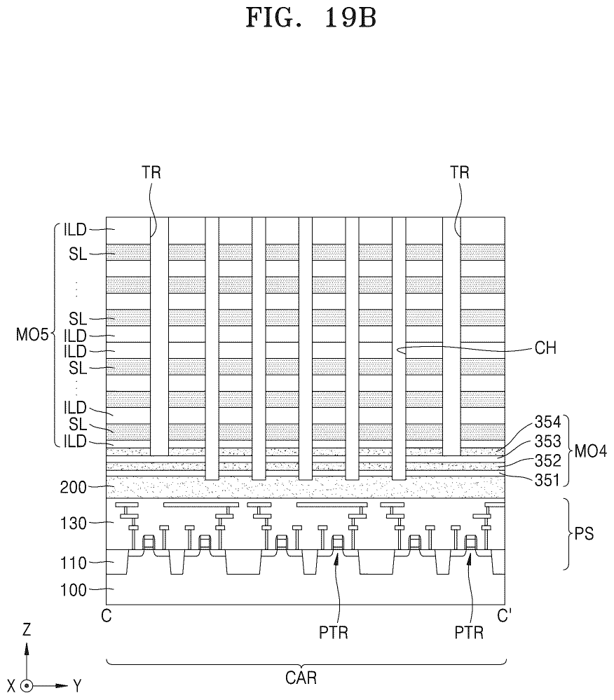

Referring to FIGS. 19A and 19B, the vertical channel holes CH, the first through-structure hole C1H, the second through-structure hole C2H, and the isolation trench TR may be simultaneously formed. The vertical channel holes CH, the first through-structure hole C1H, the second through-structure hole C2H, and the isolation trench TR may be formed by performing an etching process on the fifth mold structure MO5, the planarization insulating film 250, the fourth mold structure MO4, and the third substrate 200. The etching process may correspond to a low-temperature plasma etching process.

Each of the vertical channel holes CH may pass through the fifth mold structure MO5 and the fourth mold structure MO4. Each of the vertical channel holes CH may further pass through a portion of the third substrate 200. Portions of the upper surface of the third substrate 300 may be externally exposed by the vertical channel holes CH.

The first through-structure hole C1H may pass through the planarization insulating film 250, the fifth mold structure MO5, the fourth mold structure MO4, and the third substrate 200. The first through-structure hole C1H may further pass through a portion of the peripheral circuit insulating film 130. Some of the peripheral circuit wiring lines 195 may each be externally exposed by the first through-structure hole C1H.

The second through-structure hole C2H may pass through the planarization insulating film 250. The second through-structure hole C2H may further pass through a portion of the peripheral circuit insulating film 130. Some of the peripheral circuit wiring lines 195 may each be externally exposed by the second through-structure hole C2H.

In the cell array area CAR, the isolation trench TR may pass through the fifth mold structure MO5. The isolation trench TR may further pass through the second semiconductor film 354. A portion of the upper surface of the second buffer insulating film 353 may be exposed by the isolation trench TR.

To form the vertical channel holes CH, the first through-structure hole C1H, the second through-structure hole C2H, and the isolation trench TR, a lower-temperature plasma etching process may be used. The etching process may be performed in the same manner as the etching process that uses a low-temperature plasma etching process and has been described with reference to FIGS. 1 to 2D. For example, the first etching gas used in the etching process may include CF₃OCFCF₂. For simplicity of description, the description of the etching process using a low-temperature plasma etching process, which has been made with reference to FIGS. 1 to 2D, is omitted.

The vertical channel holes CH, the first through-structure hole C1H, the second through-structure hole C2H, and the isolation trench TR may respectively pass through different components. For example, the vertical channel holes CH pass through the structure in which the interlayer dielectrics ILD and the sacrificial films SL are alternately stacked one-by-one, whereas the second through-structure hole C2H passes through only the planarization insulating film 250 that is a single component.

In addition, the interlayer dielectric ILD and the sacrificial film SL may respectively include different insulating materials. For example, the interlayer dielectric ILD may include silicon oxide and the sacrificial film SL may include silicon nitride. The planarization insulating film 250 may include the same material as the interlayer dielectric ILD.

In the case where fluorocarbon or hydrofluorocarbon is used when an etching process for forming the vertical channel holes CH and the second through-structure hole C2H is performed, the etch rate of silicon oxide may be different from the etch rate of silicon nitride. For example, the etch rate of silicon nitride may be greater than the etch rate of silicon oxide. Therefore, during the process of etching, the second through-structure hole C2H may not be formed yet at a time point at which the vertical channel holes CH are formed. Due to the above reasons, it may be difficult to simultaneously form the vertical channel holes CH and the second through-structure hole C2H.

The method of manufacturing the semiconductor device 2000, according to one or more embodiments, may include simultaneously forming the vertical channel holes CH, the first through-structure hole C1H, the second through-structure hole C2H, and the isolation trench TR. For example, to form the vertical channel holes CH, the first through-structure hole C1H, the second through-structure hole C2H, and the isolation trench TR, a low-temperature plasma etching process may be used. The first etching gas described with reference to FIGS. 1 to 2D may be used in the low-temperature plasma etching process. Therefore, the difference between the etch rate of each of the planarization insulating film 250 and the interlayer dielectrics ILD and the etch rate of each of the sacrificial films SL may be reduced. Accordingly, the degree of difficulty and cost in a method of forming the vertical channel holes CH, the first through-structure hole C1H, the second through-structure hole C2H, and the isolation trench TR may be reduced. Eventually, the degree of difficulty and cost in the method of manufacturing the semiconductor device 2000 may be reduced.

Referring again to FIGS. 16A and 16B, the first and second vertical channel structures VS1 and VS2 may be respectively formed in the vertical channel holes CH. The first through-structure C1 may be formed in the first through-structure hole C1H. The second through-structure C2 may be formed in the second through-structure hole C2H.

After the first and second vertical channel structures VS1 and VS2 are formed, the first buffer insulating film 351, the first semiconductor film 352, and the second buffer insulating film 353 of the fourth mold structure MO4 may be removed. Removing the first buffer insulating film 351, the first semiconductor film 352, and the second buffer insulating film 353 may include performing a wet-etching process through the isolation trench TR. While the wet-etching process is being performed, a portion of the data storage pattern DSP may be removed. Next, the first source conductive pattern SCP1 may be formed to fill a space from which first buffer insulating film 351, the first semiconductor film 352, and the second buffer insulating film 353 are removed. The second semiconductor film 354 that is not removed may be referred to as the second source conductive pattern SCP2. Thus, the source structure SC including the first source conductive pattern SCP1 and the second source conductive pattern SCP2 may be formed.

During the process of forming the first through-structure C1, the protrusion PTS and the second sidewall insulating pattern CID may also be formed. Descriptions of the protrusion PTS and the second sidewall insulating pattern CID may be the same as the descriptions made with reference to FIGS. 15 to 16B.

Next, the sacrificial films SL may be selectively removed through the isolation trench TR. Selectively removing the sacrificial films SL may include performing wet-etching using phosphoric acid (H₂PO₄). The gate electrodes EL may be respectively formed in spaces from which the sacrificial films SL are removed.

The isolation structure 350 may be formed in the isolation trench TR. Next, the upper insulating film 260 may be formed on the stack structure ST and the planarization insulating film 250. The bit line contact plugs BLCP may be formed, the bit line contact plugs BLCP passing through the upper insulating film 260 and being respectively connected to the first vertical channel structures VS1 corresponding thereto. The first contact plugs C1CP may be formed, the first contact plugs C1CP passing through the upper insulating film 260 and being respectively connected to the first through-structures C1 corresponding thereto. The second contact plug C2CP may be formed, the second contact plug C2CP passing through the upper insulating film 260 and being connected to the second through-structure C2.

The bit lines BL may be formed on the upper insulating film 260, the bit lines BL being respectively connected to the bit line contact plugs BLCP corresponding thereto. The first conductive lines CL1 may be formed on the upper insulating film 260, the first conductive lines CL1 being respectively connected to the first contact plugs C1CP. The second conductive line CL2 may be formed on the upper insulating film 260, the second conductive line CL2 being connected to the second contact plug C2CP. In this way, the semiconductor device 2000 may be manufactured.

While embodiments have been described with reference to the figures, it will be understood by those of ordinary skill in the art that various changes in form and details may be made therein without departing from the spirit and scope as defined by the following claims and their equivalents.

What is claimed is:

1. A method of manufacturing a semiconductor device, the method comprising:
forming a first mold structure and a second mold structure on a semiconductor structure, wherein the second mold structure is spaced apart from the first mold structure in a horizontal direction, the first mold structure comprises first insulating films and second insulating films that are alternately stacked one-by-one, the second insulating films is different from the first insulating films, and the second mold structure comprises a third insulating film comprising a material that is the same as a material of each of the first insulating films;
forming a mask pattern on the first mold structure and the second mold structure; and
etching, using a first etching gas, the first mold structure and the second mold structure having the mask pattern formed thereon,
wherein the first etching gas comprises oxygen-containing fluorocarbon.

2. The method of claim 1, wherein the first etching gas comprises CxFyOz, where 1≤x≤5, 2x−2≤y≤2x+2, 1≤z<x, and each of x, y, and z is a natural number.

3. The method of claim 1, wherein the first etching gas comprises trifluoromethyl R(1)-O—CR(2)═CR(3)R(4), where R(1), R(2), R(3), and R(4)=CaFb, O≤a≤3, b=2a+1, and each of a and b is a natural number.

4. The method of claim 1, wherein the etching using the first etching gas is performed at a temperature in a range of −100° C. to 0° C.

5. The method of claim 1, wherein the etching using the first etching gas further comprises using a second etching gas in addition to the first etching gas, and
wherein the second etching gas comprises hydrogen (H₂).

6. The method of claim 1, wherein the etching using the first etching gas further comprises using a second etching gas in addition to the first etching gas, and
wherein the second etching gas comprises hydrogen fluoride (HF), nitrogen fluoride, phosphorus fluoride, sulfur fluoride, fluorocarbon, hydrofluorocarbon, a halogen element-containing gas, or a combination thereof.

7. The method of claim 6, wherein the halogen element-containing gas comprises hydrogen bromide (HBr), chlorine (Cl₂), or a combination thereof.

8. The method of claim 1, wherein the mask pattern comprises a silicon-based material or a carbon-based material.

9. The method of claim 1, wherein the etching using the first etching gas comprises, based on a sum of flow rates of gases except for the first etching gas being 100, supplying the first etching gas at a flow rate ratio of 100:20 to 100:40 to the first mold structure and the second mold structure.

10. A method of manufacturing a semiconductor device, the method comprising:
forming an insulating pattern on a substrate;
forming a conductive contact in the insulating pattern;
forming an etch stop film on the insulating pattern and the conductive contact;
forming a mold structure on the etch stop film, wherein the mold structure comprises a first mold film, a lower support film, a second mold film, and an upper support film that are stacked in order, each of the first mold film and the second mold film comprises a first material, each of the lower support film and the upper support film comprises a second material, and the first material and the second material have etch selectivities with respect to each other;
forming a mask pattern on the mold structure; and
etching, using a first etching gas, the mold structure having the mask pattern formed thereon,
wherein a via hole is formed through the mold structure and the etch stop film by the etching, and
wherein the first etching gas comprises oxygen-containing fluorocarbon.

11. The method of claim 10, further comprising:
after the etching using the first etching gas,
forming a lower electrode to fill the via hole;
forming a dielectric film contacting the lower electrode; and
forming an upper electrode spaced apart from the lower electrode with the dielectric film between the lower electrode and the upper electrode.

12. The method of claim 10, wherein the first etching gas comprises CxFyOz, where 1≤x≤5, 2x−2≤y≤2x+2, 1≤z<x, and each of x, y, z is a natural number.

13. The method of claim 10, wherein the first etching gas comprises trifluoromethyl R(1)-O—CR(2)═CR(3)R(4), where R(1), R(2), R(3), and R(4)=CaFb, O≤a≤3, b=2a+1, and each of a and b is a natural number.

14. The method of claim 10, wherein the etching using the first etching gas is performed at temperature in a range of −100° C. to 0° C.

15. The method of claim 10, wherein the etching using the first etching gas further comprises using a second etching gas in addition to the first etching gas, and
wherein the second etching gas comprises hydrogen, hydrogen fluoride (HF), nitrogen fluoride, phosphorus fluoride, sulfur fluoride, fluorocarbon, hydrofluorocarbon, a halogen element-containing gas, or a combination thereof.

16. A method of manufacturing a semiconductor device, the method comprising:
forming a peripheral circuit structure on a first substrate, the first substrate comprising a cell array area and a contact area that is adjacent to the first substrate, and the peripheral circuit structure comprising peripheral circuit transistors;
forming a mold structure on the peripheral circuit structure, wherein the mold structure comprises interlayer dielectrics and sacrificial films that are alternately stacked one-by-one, each of the interlayer dielectrics comprises a first material, each of the sacrificial films comprises a second material, and the first material and the second material respectively have etch selectivities with respect to each other;
trimming the mold structure to have a stepped structure in the contact area;
forming a planarization insulating film on the stepped structure; and
forming vertical channel holes, a first through-structure hole, and a second through-structure hole simultaneously such that the vertical channel holes pass through the mold structure in the cell array area, the first through-structure hole passes through the planarization insulating film and the mold structure in the contact area, and the second through-structure hole passes through the planarization insulating film in the contact area,
wherein the forming the vertical channel holes, the first through-structure hole, and the second through-structure hole comprises etching, using a first etching gas, the mold structure and the planarization insulating film, and
wherein the first etching gas comprises oxygen-containing fluorocarbon.

17. The method of claim 16, wherein the first etching gas comprises CxFyOz, where 1≤x≤5, 2x−2≤y≤2x+2, 1≤z<x, and each of x, y, z is a natural number.

18. The method of claim 16, wherein the first etching gas comprises trifluoromethyl R(1)-O—CR(2)═CR(3)R(4), where R(1), R(2), R(3), and R(4)=CaFb, O≤a≤3, b=2a+1, and each of a and b is a natural number.

19. The method of claim 16, wherein the forming of the vertical channel holes, the first through-structure hole, and the second through-structure hole is performed at a temperature in a range of −100° C. to 0° C.

20. The method of claim 16, wherein the etching further comprises using a second etching gas that is different from the first etching gas in addition to the first etching gas, and
wherein the second etching gas comprises hydrogen, hydrogen fluoride (HF), nitrogen fluoride, phosphorus fluoride, sulfur fluoride, fluorocarbon, hydrofluorocarbon, a halogen element-containing gas, or a combination thereof.
